(19) United States
(12) Patent Application Publication
(10) Pub. No.: US 2026/0182103 A1
(43) Pub. Date: Jun. 25, 2026

(54) LIGHT EMITTING CHIP, LIGHT EMITTING SUBSTRATE, BACKLIGHT MODULE AND DISPLAY DEVICE

(71) Applicant: BOE Technology Group Co., Ltd., Beijing (CN)

(72) Inventors: Xianqin MENG, Beijing (CN); Weiting PENG, Beijing (CN); Zhongxiao LI, Beijing (CN); Yun LAI, Beijing (CN); Wei WANG, Beijing (CN); Qiuyu LING, Beijing (CN); Zhiqiang JIAO, Beijing (CN); Kang GUO, Beijing (CN); Mingxing WANG, Beijing (CN); Qian SUN, Beijing (CN)

(21) Appl. No.: 18/832,105

(22) PCT Filed: Mar. 27, 2023
(86) PCT No.: PCT/CN2023/083982

§ 371 Date: Jul. 23, 2024

(51) Int. Cl. H10H 20/855; H10H 20/812; H10H 20/841

(52) U.S. Cl. CPC H10H 20/855; H10H 20/812; H10H 20/841

(57) ABSTRACT

A light emitting chip includes a light emitting layer, a polarization structure, an auxiliary structure and a dielectric layer. The light emitting layer includes first and second semiconductor layers, and a quantum well layer therebetween. The polarization structure is on a side of the second semiconductor layer away from the quantum well layer, and allows first linear polarized light in emitted light to exit and reflects second linear polarized light. The auxiliary structure is on a side of the polarization structure facing the light emitting layer, and converts the second linear polarized light reflected into light including first linear polarized light and propagating toward the polarization structure. The dielectric layer is in direct contact with the second semiconductor layer.

### CROSS-REFERENCE TO RELATED APPLICATION

The present disclosure is a US national phase of PCT application No. PCT/CN2023/083982 filed on Mar. 27, 2023, the entire contents of which are incorporated herein by reference.

### TECHNICAL FIELD

The present application relates to the field of display technologies, and in particular, to a light emitting chip, a light emitting substrate, a backlight module and a display device.

### BACKGROUND

Mini-LEDs and Micro LEDs are novel LED display technologies derived from small-pitch LEDs, and are also known as sub-millimeter LEDs. Due to their good display effect and light and thin experience, as well as their advantages such as high contrast and long service life, they have obvious use trend in the display field.

### SUMMARY

The present application provides a light emitting chip, a light emitting substrate, a backlight module and a display device.

According to a first aspect of the embodiments of the present application, a light emitting chip is provided. The light emitting chip includes:
a light emitting layer including a first semiconductor layer, a second semiconductor layer, and a quantum well layer located between the first semiconductor layer and the second semiconductor layer;
a polarization structure located on a side of the second semiconductor layer away from the quantum well layer, and configured to allow first linear polarized light in light emitted from the light emitting layer to exit and reflect second linear polarized light in the light emitted from the light emitting layer, where a vibration direction of the first linear polarized light is perpendicular to a vibration direction of the second linear polarized light;
an auxiliary structure located on a side of the polarization structure facing the light emitting layer, and configured to convert the second linear polarized light reflected by the polarization structure into light including the first linear polarized light and propagating toward the polarization structure;
a low refraction layer located on a side of the second semiconductor layer away from the quantum well layer, and in direct contact with the second semiconductor layer, where a difference Δn1 between a refractive index of the second semiconductor layer and a refractive index of the low refraction layer satisfies the following condition: 0.5≤Δn1≤1.0.

In an embodiment, the polarization structure includes a plurality of periodically arranged wire grids, and each wire grid includes a metal layer and an inorganic material layer located on a side of the metal layer away from the second semiconductor layer, where a thickness of the inorganic material layer is greater than a thickness of the metal layer.

In an embodiment, the polarization structure includes a plurality of periodically arranged wire grids, and each wire grid includes a metal layer and an inorganic material layer located on a side of the metal layer facing the second semiconductor layer; the low refraction layer is located between the second semiconductor layer and the polarization structure, where a thickness of the inorganic material layer is greater than a thickness of the low refraction layer.

In an embodiment, a period of the wire grids is in a range of 40 nm˜200 nm, a width of the wire grids is in a range of 10 nm˜70 nm, a thickness of the metal layer is in a range of 60 nm˜160 nm, the thickness of the inorganic material layer is in a range of 120 nm˜200 nm, and the thickness of the low refraction layer is in a range of 0 nm˜40 nm or 120 nm˜180 nm.

In an embodiment, the polarization structure includes a plurality of periodically arranged wire grids, and each wire grid includes a metal layer; the low refraction layer is located between the second semiconductor layer and the polarization structure, and the metal layer is in direct contact with the low refraction layer.

In an embodiment, a period of the wire grids is in a range of 40 nm˜200 nm, a width of the wire grids is in a range of 10 nm˜70 nm, a thickness of the metal layer is in a range of 60 nm˜160 nm, and a thickness of the low refraction layer is in a range of 0 nm˜40 nm or 120 nm˜180 nm.

In an embodiment, the polarization structure includes a plurality of periodically arranged wire grids; the low refraction layer is located between the second semiconductor layer and the polarization structure; the light emitting chip further includes an organic layer located on a side of the low refraction layer away from the second semiconductor layer and in direct contact with the low refraction layer, and the organic layer includes at least organic structures located between adjacent wire grids, where a difference Δn2 between a refractive index of the low refraction layer and a refractive index of the organic layer is ≤0.4.

In an embodiment, each wire grid consists of a metal layer, and the metal layer is in direct contact with the low refraction layer;

a period of the wire grids is in a range of 40 nm˜200 nm, a width of the wire grids is in a range of 40 nm˜60 nm, a thickness of the metal layer is in a range of 70 nm˜90 nm, and a thickness of the low refraction layer is in a range of 10 nm˜30 nm or 170 nm˜200 nm.

In an embodiment, the polarization structure includes a plurality of periodically arranged wire grids, and each wire grid includes a metal layer and an inorganic material layer located on a side of the metal layer facing the second semiconductor layer;

the low refraction layer includes a plurality of low refraction structures, the low refraction structures are located between adjacent wire grids, and a material for the low refraction layer is an organic material; or the low refraction layer is located between the inorganic material layer and the second semiconductor layer; the light emitting chip further includes an organic layer located on a side of the low refraction layer away from the second semiconductor layer and in direct contact with the low refraction layer, and the organic layer includes organic structures located between adjacent wire grids, or the organic layer includes organic structures located between adjacent wire grids and an organic material film layer located between the inorganic material layer and the low refraction layer.

In an embodiment, a period of the wire grids is in a range of 40 nm˜200 nm, a width of the wire grids is in a range of 40 nm˜60 nm, a thickness of the metal layer is in a range of 100 nm˜120 nm, and a distance between a surface of the inorganic material layer away from the second semiconductor layer and a surface of the low refraction layer facing the second semiconductor layer is in a range of 170 nm˜200 nm.

In an embodiment, the light emitting chip further includes a protection layer located on a side of the polarization structure away from the light emitting layer.

In an embodiment, the polarization structure includes a plurality of periodically arranged wire grids;
the low refraction layer is located between the light emitting layer and the polarization structure; the light emitting chip further includes an organic layer located on a side of the low refraction layer away from the light emitting layer and in direct contact with the low refraction layer, and the organic layer includes at least organic structures located between adjacent wire grids, where a difference Δn3 between a refractive index of the organic layer and a refractive index of the protection layer is ≤0.4; or
the low refraction layer includes low refraction structures located between adjacent wire grids, and a material for the low refraction layer is an organic material, where a difference Δn4 between a refractive index of the low refraction layer and a refractive index of the protection layer is ≤0.4.

In an embodiment, the light emitting chip further includes a reflective film layer surrounding side portions of the light emitting layer; or

the light emitting chip further includes a light absorption film layer surrounding the side portions of the light emitting layer and configured to absorb light emitted from the side portions of the light emitting layer.

In an embodiment, the auxiliary structure includes a reflection layer or a scattering and reflection layer located on a side of the light emitting layer away from the polarization structure; or
the auxiliary structure includes a reflective material layer located on a side of the light emitting layer away from the polarization structure and a first polarization film layer located between the polarization structure and the reflective material layer, and the first polarization film layer is configured to shift a phase of light passing through the first polarization film layer by π/2; or
the auxiliary structure includes a second polarization film layer located on a side of the light emitting layer away from the polarization structure, and the second polarization film layer is configured to reflect the second linear polarized light and convert the second linear polarized light into the first linear polarized light.

According to a second aspect of the embodiments of the present application, a light emitting substrate is provided. The light emitting substrate includes a driving circuit layer and a plurality of light emitting chips as mentioned above, where the driving circuit layer includes one or more driving circuits for driving the light emitting chips.

In an embodiment, the light emitting substrate includes a light emitting chip with a color of light emitted being red, a light emitting chip with a color of light emitted being green, and a light emitting chip with a color of light emitted being blue;

a wavelength of the light emitted from the light emitting chip with the with a color of light emitted being red is in a range of 640 nm˜700 nm; a wavelength of the light emitted from the light emitting chip with the with a color of light emitted being green is in a range of 500 nm˜580 nm; and a wavelength of the light emitted from the light emitting chip with the with a color of light emitted being blue is in a range of 430 nm˜490 nm.

In an embodiment, the light emitting substrate further includes light absorption structures located between adjacent light emitting chips; or
the light emitting substrate further includes an absorption layer located on a light emitting side of the light emitting chips, and provided with through holes, where orthographic projections of light emitting layers of the light emitting chips on the absorption layer coincide with the through holes respectively; or
the light emitting substrate further includes a reflective thin film layer located on the light emitting side of the light emitting chips, and provided with openings, where orthographic projections of the light emitting layers of the light emitting chips on the reflective thin film layer coincide with the openings respectively.

According to a third aspect of the embodiments of the present application, a backlight module is provided including a light emitting substrate as mentioned above.

In an embodiment, the light emitting chips are located on a side of the driving circuit layer, and a light emitting side of the light emitting chips faces away from the driving circuit layer; or

the backlight module includes a light guide plate located on a side of the driving circuit layer, and the light emitting chips are located on a side portion of the light guide plate.

In an embodiment, the backlight module further includes: a brightness enhancement film located on a light emitting side of a light emitting chip.

According to a fourth aspect of the embodiments of the present application, a display device is provided. The display device includes a liquid crystal display panel and a backlight module as mentioned above; or

the display device includes a display panel, where the display panel is a light emitting substrate as mentioned above.

In the light emitting chip, the light emitting substrate, the backlight module and the display device provided in the embodiments of the present application, the first linear polarized light in the light emitted from the light emitting layer exits through the polarization structure, the second linear polarized light is reflected by the polarization structure, the auxiliary structure converts the reflected second linear polarized light into the light including the first linear polarized light and propagating toward the polarization structure, and the first linear polarized light in the light can exit through the polarization structure, so that a light utilization rate of the light emitting chip can be improved. By setting the difference Δn1 between the refractive index of the second semiconductor layer and the refractive index of the low refraction layer to satisfy the following condition: 0.5≤Δn1≤1.0, it is helpful to increase an exit amount of light emitted from the light emitting layer and further improve a light utilization rate of the light emitting chip.

### BRIEF DESCRIPTION OF DRAWINGS

FIG. 1 is a cross-sectional view showing a light emitting chip according to an exemplary embodiment of the present application;

FIG. 2 is a cross-sectional view showing a light emitting chip according to another exemplary embodiment of the present application;

FIG. 3 is a cross-sectional view showing a light emitting chip according to another exemplary embodiment of the present application;

FIG. 4 is a cross-sectional view showing a light emitting chip according to another exemplary embodiment of the present application;

FIG. 5 is a cross-sectional view showing a light emitting chip according to another exemplary embodiment of the present application;

FIG. 6 is a cross-sectional view showing a light emitting chip according to another exemplary embodiment of the present application;

FIG. 7 is a cross-sectional view showing a light emitting chip according to another exemplary embodiment of the present application;

FIG. 8 is a cross-sectional view showing a light emitting chip according to another exemplary embodiment of the present application;

FIG. 9 is a cross-sectional view showing a light emitting chip according to another exemplary embodiment of the present application;

FIG. 10 is a curve graph showing relationships of a transmissivity for first linear polarized light and a polarization degree of exit light with a period of a wire grid in a light emitting chip according to an exemplary embodiment of the present application;

FIG. 11 is a curve graph showing a relationship between a transmissivity for first linear polarized light and a wavelength of light in a light emitting chip according to an exemplary embodiment of the present application;

FIG. 12 is a curve graph showing relationships of a transmissivity for first linear polarized light and a polarization degree of exit light with a thickness of a metal layer in a light emitting chip according to an exemplary embodiment of the present application;

FIG. 13 is a curve graph showing a relationship between a transmissivity for first linear polarized light and a wavelength of light in a light emitting chip according to another exemplary embodiment of the present application;

FIG. 14 is a curve graph showing relationships of a transmissivity for first linear polarized light and a polarization degree of exit light with a width of a wire grid in a light emitting chip according to an exemplary embodiment of the present application;

FIG. 15 is a curve graph showing a relationship between a transmissivity for first linear polarized light and a wavelength of light according to another exemplary embodiment of the present application;

FIG. 16 is a curve graph showing relationships of a transmissivity for first linear polarized light and a polarization degree of exit light with a thickness of an inorganic material layer in a light emitting chip according to an exemplary embodiment of the present application;

FIG. 17 is a curve graph showing a relationship between a transmissivity for first linear polarized light and a wavelength of light according to another exemplary embodiment of the present application;

FIG. 18 is a curve graph showing relationships of a transmissivity for first linear polarized light and a polarization degree of exit light with a thickness of a low refraction layer in a light emitting chip according to an exemplary embodiment of the present application;

FIG. 19 is a curve graph showing a relationship between a transmissivity for first linear polarized light and a wavelength of light according to another exemplary embodiment of the present application;

FIG. 20 is a curve graph showing relationships of a transmissivity for first linear polarized light and a polarization degree of exit light with a refractive index of a low refraction layer in a light emitting chip according to an exemplary embodiment of the present application;

FIG. 21 is a curve graph showing a relationship between a transmissivity for first linear polarized light and a wavelength of light according to another exemplary embodiment of the present application;

FIG. 22 is a curve graph showing relationships of a transmissivity for first linear polarized light and a polarization degree of exit light with a period of a wire grid in a light emitting chip according to another exemplary embodiment of the present application;

FIG. 23 is a curve graph showing a relationship between a transmissivity for first linear polarized light and a wavelength of light according to another exemplary embodiment of the present application;

FIG. 24 is a curve graph showing relationships of a transmissivity for first linear polarized light and a polarization degree of exit light with a thickness of a metal layer in a light emitting chip according to another exemplary embodiment of the present application;

FIG. 25 is a curve graph showing a relationship between a transmissivity for first linear polarized light and a wavelength of light according to another exemplary embodiment of the present application;

FIG. 26 is a curve graph showing relationships of a transmissivity for first linear polarized light and a polarization degree of exit light with a thickness of a metal layer in a light emitting chip according to another exemplary embodiment of the present application;

FIG. 27 is a curve graph showing a relationship between a transmissivity for first linear polarized light and a wavelength of light according to another exemplary embodiment of the present application;

FIG. 28 is a curve graph showing relationships of a transmissivity for first linear polarized light and a polarization degree of exit light with a thickness of a metal layer in a light emitting chip according to another exemplary embodiment of the present application;

FIG. 29 is a curve graph showing a relationship between a transmissivity for first linear polarized light and a wavelength of light in a light emitting chip according to another exemplary embodiment of the present application;

FIG. 30 is a curve graph showing relationships of a transmissivity for first linear polarized light and a polarization degree of exit light with a thickness of a low refraction layer in a light emitting chip according to another exemplary embodiment of the present application;

FIG. 31 is a curve graph showing a relationship between a transmissivity for first linear polarized light and a wavelength of light in a light emitting chip according to another exemplary embodiment of the present application;

FIG. 32 is a curve graph showing relationships of a transmissivity for first linear polarized light and a polarization degree of exit light with a refractive index of a low refraction layer in a light emitting chip according to another exemplary embodiment of the present application;

FIG. 33 is a curve graph showing a relationship between a transmissivity for first linear polarized light and a wavelength of light in a light emitting chip according to another exemplary embodiment of the present application;

FIG. 34 is a structural schematic diagram showing a backlight module according to an exemplary embodiment of the present application;

FIG. 35 is a structural schematic diagram showing a backlight module according to another exemplary embodiment of the present application;

FIG. 36 is a structural schematic diagram showing a display device according to an exemplary embodiment of the present application;

FIG. 37 is a structural schematic diagram showing a display device according to another exemplary embodiment of the present application;

FIG. 38 is a cross-sectional view showing a light emitting chip according to another exemplary embodiment of the present application;

FIG. 39 is a structural schematic diagram showing a light-emitting substrate according to an exemplary embodiment of the present application;

FIG. 40 is a structural schematic diagram showing a light-emitting substrate according to an exemplary embodiment of the present application;

FIG. 41 is a structural schematic diagram showing a light-emitting substrate according to an exemplary embodiment of the present application.

### DETAILED DESCRIPTION

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present application. Rather, they are merely examples of apparatuses and methods consistent with some aspects of the present application as detailed in the appended claims.

The terms used in the present application are for the purpose of describing particular examples only, and are not intended to limit the present application. Terms determined by “a”, “the” and “said” in their singular forms in the present application and the appended claims are also intended to include plurality, unless clearly indicated otherwise in the context. It should also be understood that the term “and/or” as used herein refers to and includes any and all possible combinations of one or more of the associated listed items.

It is to be understood that, although terms “first,” “second,” “third,” and the like may be used in the present application to describe various information, such information should not be limited to these terms. These terms are only used to distinguish one category of information from another. For example, without departing from the scope of the present application, first information may be referred as second information; and similarly, second information may also be referred as first information. Depending on the context, the word “if” as used herein may be interpreted as “when” or “upon” or “in response to determining”.

The embodiments of the present application provide a light emitting chip, a light emitting substrate, a backlight module and a display device. The light emitting chip, the light emitting substrate, the backlight module and the display device in the embodiments of the present application will be described in detail below with reference to the accompanying drawings. In a case of no conflict, features in the embodiments described below may be complemented or combined with each other.

Embodiments of the present application provide a light emitting chip. As shown in FIG. 1 to FIG. 3, the light emitting chip includes a light emitting layer 10, a polarization structure 20, an auxiliary structure 30 and a dielectric layer/low refraction layer 40.

The light emitting layer 10 includes a first semiconductor layer 11, a second semiconductor layer 12, and a quantum well layer 13 located between the first semiconductor layer 11 and the second semiconductor layer 12. The polarization structure 20 is located on a side of the second semiconductor layer 12 away from the quantum well layer 13, and the polarization structure 20 is configured to allow first linear polarized light in light emitted from the light emitting layer 10 to exit and reflect second linear polarized light in the light emitted from the light emitting layer 10, where a vibration direction of the first linear polarized light is perpendicular to a vibration direction of the second linear polarized light. The auxiliary structure 30 is located on a side of the polarization structure 20 facing the light emitting layer 10, and is configured to convert the second linear polarized light reflected by the polarization structure 20 into light including the first linear polarized light and propagating toward the polarization structure 20. The low refraction layer 40 is located on a side of the second semiconductor layer away from the quantum well layer, and is in direct contact with the second semiconductor layer. A refractive index of the low refraction layer 40 is less than a refractive index of the second semiconductor layer 12. A difference Δn between the refractive index of the second semiconductor layer 12 and the refractive index of the low refraction layer 40 satisfies the following condition: 0.5≤Δn1≤1.0.

In the light emitting chip provided in the embodiments of the present application, the first linear polarized light in the light emitted from the light emitting layer exits through the polarization structure, the second linear polarized light is reflected by the polarization structure, the auxiliary structure converts the reflected second linear polarized light into the light including the first linear polarized light and propagating toward the polarization structure, and the first linear polarized light in the light can exit through the polarization structure, so that a light utilization rate of the light emitting chip can be improved. By setting the difference Δn1 between the refractive index of the second semiconductor layer and the refractive index of the low refraction layer to satisfy the following condition: 0.5≤Δn1≤1.0, it is helpful to increase an exit amount of light emitted from the light emitting layer and further improve a light utilization rate of the light emitting chip.

In an embodiment, as shown in FIG. 1 to FIG. 3, the light emitting chip further includes a base plate 50 located on a side of the light emitting layer 10 away from the polarization structure 20, and the light emitting layer 10 is formed on the base plate 50. Materials of the base plate 50 may include glass, sapphire, polyethylene terephthalate (PET), polycarbonate (PC) or the like, and may alternatively include an organic resin material, such as epoxy resin, triazine, silicon resin, or polyimide. In some exemplary embodiments, the base plate may be a printed circuit board (PCB) of an FR4 type, or a flexible PCB that is easily deformable. In some exemplary embodiments, the base plate may include a ceramic material, such as silicon nitride, AlN or Al₂O₃, or metal or a metal/metallic compound, and the base plate may be, for example, a metal core printed circuit board (MCPCB) or a metal copper-clad laminate (MCCL).

In an embodiment, in the light emitting layer 10, one of the first semiconductor layer 11 and the second semiconductor layer 12 is an N-type semiconductor layer, and other one of the first semiconductor layer 11 and the second semiconductor layer 12 is a P-type semiconductor layer. For example, the first semiconductor layer 11 is a P-type semiconductor layer, and the second semiconductor layer 12 is an N-type semiconductor layer.

In an embodiment, the auxiliary structure 30 includes a reflective material layer located on a side of the light emitting layer 10 away from the polarization structure 20 and a first polarization film layer located between the polarization structure 20 and the reflective material layer, and the first polarization film layer is configured to shift a phase of light passing therethrough by π/2. With such a configuration, after the second linear polarized light reflected by the polarization structure 20 passes through the first polarization film layer, a phase of the second linear polarized light is shifted by π/2, then the second linear polarized light is reflected by the reflective material layer and passes through the first polarization film layer again, and a phase of the second linear polarized light is shifted by π/2 again, that is, the second linear polarized light is converted into the first linear polarized light propagating toward the polarization structure and exits through the polarization structure 20. In this way, light reflected by the polarization structure is substantially completely converted into the first linear polarized light to exit under the action of the first polarization film layer and the reflective material layer, avoiding a light loss caused by passing of light through the light emitting layer and the low refraction layer for multiple times. The first polarization film layer may be of a ¼ wave plate structure. A transmissivity of the first polarization film layer may be greater than 90%. The reflective material layer may be a metal reflection layer, for example, the reflective material layer may be an Ag film layer with a thickness of about 100 nm; or the reflective material layer may include a plurality of film layers. For example, the reflective material layer is a distributed Bragg reflector.

In some embodiments, as shown in FIG. 1 to FIG. 3, the first polarization film layer 31 is located on a side of the light emitting layer 10 away from the polarization structure 20, and the reflective material layer 32 is located on a side of the first polarization film layer 31 away from the light emitting layer 10. Specifically, the first polarization film layer 31 is located on a side of the base plate 50 away from the polarization structure 20. In other embodiments, the first polarization film layer 31 may be located between the low refraction layer 40 and the second semiconductor layer 12.

In another embodiment, the auxiliary structure 30 includes a reflection layer located on a side of the light emitting layer 10 away from the polarization structure 20. The reflection layer reflects the second linear polarized light. When the second linear polarized light passes through the light emitting layer 10, at least part of the light is depolarized by film layer(s) of the light emitting layer 10 to become natural light. The first linear polarized light in the natural light exits through the polarization structure 20. The second linear polarized light is reflected by the polarization structure 20, and is incident into the reflection layer. The above process is repeated. The reflection layer may be a metal reflection layer, for example, the reflection layer may be an Ag film layer with a thickness of about 100 nm; or the reflection layer may include a plurality of film layers, for example, the reflection layer is a distributed Bragg reflector.

In another embodiment, the auxiliary structure 30 includes a scattering and reflection layer located on a side of the light emitting layer 10 away from the polarization structure 20. The second linear polarized light reflected by the polarization structure 20 is scattered on a surface of the scattering and reflection layer to be converted into natural light and reflected. The first linear polarized light in the natural light exits through the polarization structure 20. The second linear polarized light in the natural light is reflected by the polarization structure 20, and is incident into the scattering and reflection layer. The above process is repeated.

In another embodiment, the auxiliary structure 30 includes a second polarization film layer located on a side of the light emitting layer 10 away from the polarization structure 20, and the second polarization film layer is configured to reflect the second linear polarized light and convert the second linear polarized light into the first linear polarized light. That is, the second polarization film layer integrates two functions of reflection and polarization rotation. In this way, light reflected by the polarization structure is substantially completely converted into the first linear polarized light to exit under the action of the second polarization film layer, avoiding a light loss caused by passing of light through the light emitting layer and the low refraction layer for multiple times.

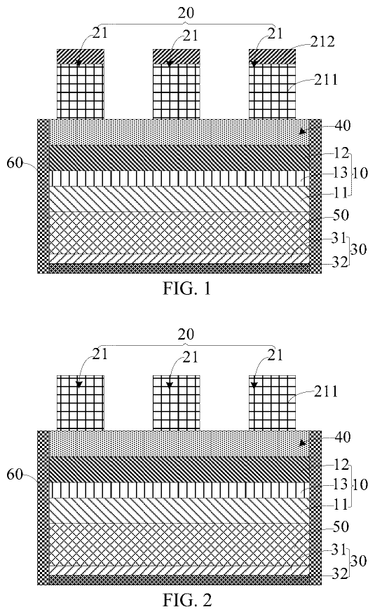

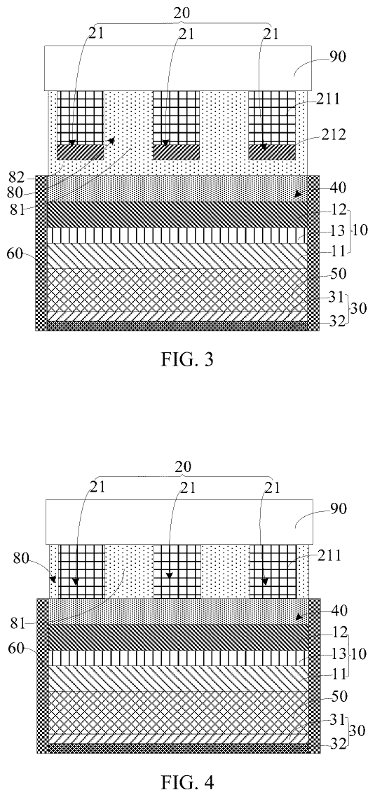

In an embodiment, as shown in FIG. 1 to FIG. 3, the polarization structure includes a plurality of periodically arranged wire grids 21, and each wire grid 21 includes at least a metal layer 211. In the embodiments shown in FIG. 1 and FIG. 3, the wire grid 21 includes a metal layer 211 and an inorganic material layer 212 located on a side of the metal layer 211. In the embodiment shown in FIG. 1, the inorganic material layer 212 is located on a side of the metal layer 211 away from the second semiconductor layer 12. In the embodiment shown in FIG. 3, the inorganic material layer 212 is located on a side of the metal layer 211 facing the second semiconductor layer 12. In the embodiment shown in FIG. 2, the wire grid 21 includes only a metal layer 211.

In an embodiment, a material for the metal layer 211 may be aluminum, and a material for the inorganic material layer 212 may be silicon dioxide. In this way, the polarization structure may have a relatively high transmissivity and a relatively low absorptivity for the first linear polarized light.

In an embodiment, as shown in FIG. 1 and FIG. 2, the low refraction layer 40 is located between the second semiconductor layer 12 and the polarization structure 20, and the metal layer 211 of the wire grid 21 is in direct contact with the low refraction layer 40.

In an embodiment, as shown in FIG. 3 to FIG. 6, the light emitting chip further includes a protection layer 90 located on a side of the polarization structure 20 away from the light emitting layer 10. The protection layer 90 may protect the polarization structure 20.

In an embodiment, a materials for the protection layer 90 is glass, sapphire, PET, PC, or the like. In this way, a light transmissivity of the protection layer 90 may be relatively high to reduce the influence on exit light; and a hardness of the protection layer 90 may be relatively high to improve an anti-compression capability and an anti-collision capability of the light emitting chip, so that a protection effect on film layers below is better.

In an embodiment, the polarization structure 20 may be formed on the protection layer 90, and the polarization structure 20 is attached to the light emitting layer 10.

In an embodiment, as shown in FIG. 3 to FIG. 6, the light emitting chip further includes an organic layer 80, and the organic layer 80 includes at least organic structures 81 located between adjacent wire grids 21. The polarization structure 20 is adhered together with film layers below through the organic layer 80. A material for the organic layer 80 may be, for example, an organic resin. In the embodiment shown in FIG. 3, the organic layer 80 includes organic structures 81 located between adjacent wire grids 21 and an organic material film layer 82 located between the wire grids 21 and the low refraction layer 40. In the embodiments shown in FIG. 4 and FIG. 6, the organic layer 80 consists of organic structures 81 located between adjacent wire grids 21.

In an embodiment, as shown in FIG. 3, FIG. 4 and FIG. 6, the low refraction layer 40 is located between the second semiconductor layer 12 and the polarization structure 20, and the organic layer 80 is located on a side of the low refraction layer 40 away from the second semiconductor layer 12. A difference Δn2 between the refractive index of the low refraction layer 40 and a refractive index of the organic layer 80 is ≤0.4. With such a configuration, it is helpful to increase an exit amount of light emitted from the light emitting layer and further improve a light utilization rate of the light emitting chip.

Further, a difference Δn3 between the refractive index of the organic layer 80 and a refractive index of the protection layer 90 is ≤0.4. In this way, an exit amount of light emitted from the light emitting layer may be further increased, and a light utilization rate of the light emitting chip is further improved.

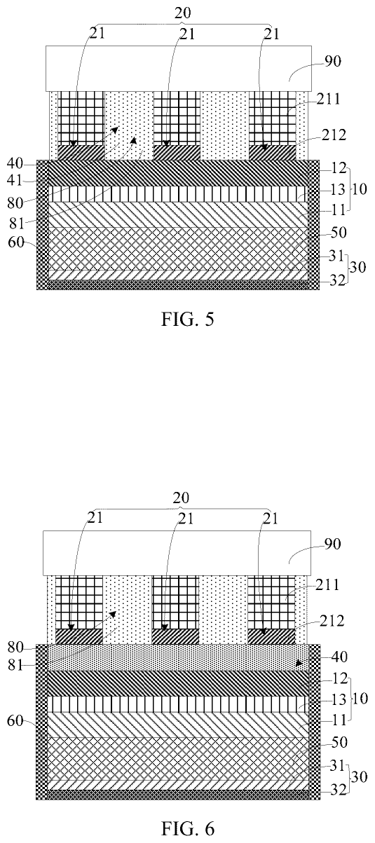

In an embodiment, as shown in FIG. 5, the wire grids 21 are in direct contact with the second semiconductor layer 12, and the low refraction layer 40 includes a plurality of low refraction structures 41. The low refraction structures 41 are located between adjacent wire grids 21, and a material for the low refraction layer 40 is an organic material. A difference Δn4 between the refractive index of the low refraction layer 40 and the refractive index of the protection layer 90 is ≤0.4. With such a configuration, it is helpful to increase an exit amount of light emitted from the light emitting layer and further improve a light utilization rate of the light emitting chip. In this embodiment, the organic structures 81 of the organic layer 80 serve as the low refraction structures 41.

Further, a difference Δn4 between the refractive index of the low refraction layer 40 and the refractive index of the protection layer 90 is ≤0.4. In this way, an exit amount of light emitted from the light emitting layer may be further increased, and a light utilization rate of the light emitting chip is further improved.

In an embodiment, a process of forming the polarization structure 20 in the embodiments shown in FIG. 1 to FIG. 6 may be as follows:

First, a metal film layer and an inorganic material film layer located on the metal film layer are sequentially deposited. In the embodiments shown in FIG. 1 and FIG. 2, the metal film layer is formed on the low refraction layer 40. In the embodiments shown in FIG. 3 to FIG. 6, the metal film layer is formed on the protection layer 90.

Then, a patterned mask layer is formed on the inorganic material film layer.

A patterned mask layer may be obtained by coating an imprinting adhesive film layer, then imprinting the coated imprinting adhesive film layer with a hard template or a soft template to pattern the imprinting adhesive film layer, and curing the patterned imprinting adhesive film layer. For example, the imprinting adhesive film layer may be cured by means of ultraviolet irradiation.

Next, the inorganic material film layer is etched by using the patterned mask layer as a shield to obtain a plurality of inorganic material layers arranged at intervals.

Subsequently, the metal film layer is etched by using the patterned mask layer and the inorganic material layers as shielding to obtain a plurality of metal layers arranged at intervals.

Then, the mask layer is removed to obtain the wire grids including the inorganic material layers and the metal layers; or both the mask layer and the inorganic material layers are removed to obtain the wire grids including only the metal layers. Thus, the polarization structure including a plurality of wire grids is obtained.

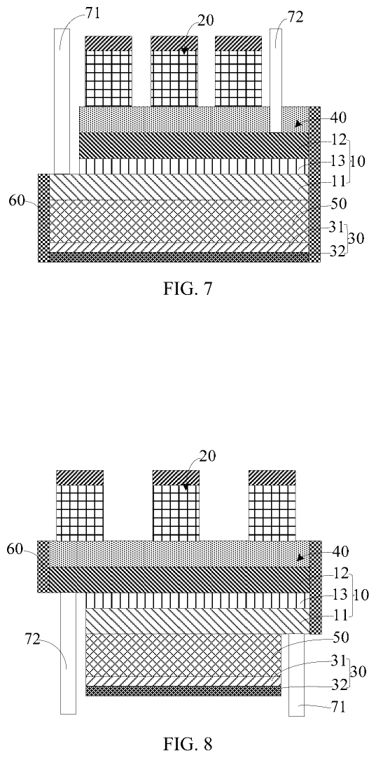

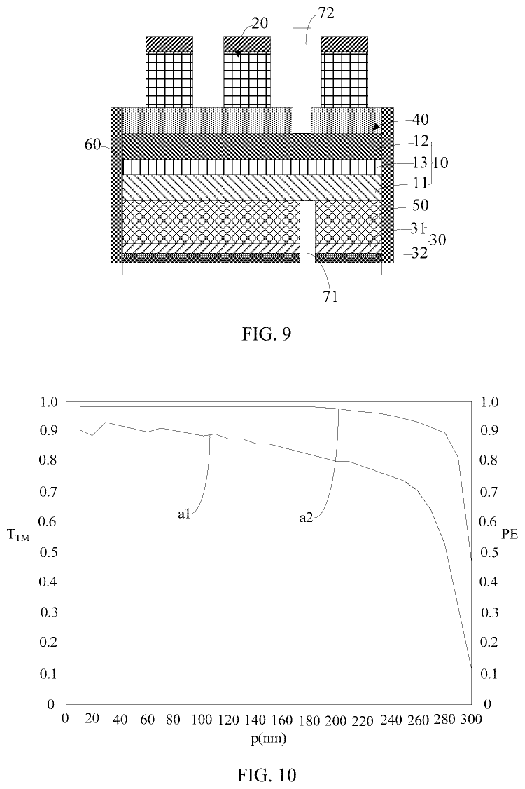

In an embodiment, as shown in FIG. 7 to FIG. 9, the light emitting chip further includes a first electrode 71 and a second electrode 72. The first electrode 71 is electrically connected to the first semiconductor layer 11, and the second electrode 72 is electrically connected to the second semiconductor layer 12. In the embodiment shown in FIG. 7, the light emitting chip is a normal chip, and both the first electrode 71 and the second electrode 72 are located on a side of the first semiconductor layer 11 facing the second semiconductor layer 12. In the embodiment shown in FIG. 8, the light emitting chip is a flip chip, and both the first electrode 71 and the second electrode 72 are located on a side of the second semiconductor layer 12 away from the first semiconductor layer 11. In the embodiment shown in FIG. 9, the light emitting chip is a vertical chip, the first electrode 71 is located on a side of the first semiconductor layer 11 away from the second semiconductor layer 12, and the second electrode 72 is located on a side of the second semiconductor layer 12 away from the first semiconductor layer 11.

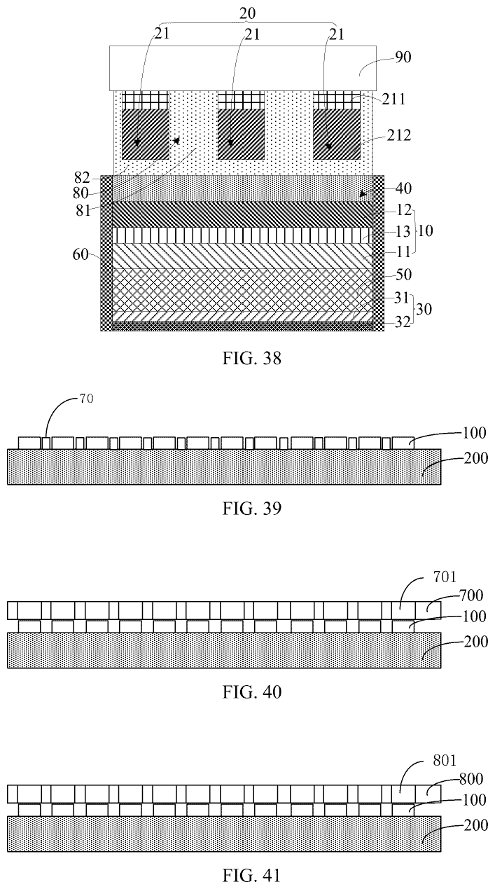

In an embodiment, as shown in FIG. 38, when the wire grid 21 includes a metal layer 211 and an inorganic material layer 212 located on a side of the metal layer 211 facing the second semiconductor layer 12, a thickness of the inorganic material layer 212 is greater than a thickness of the metal layer 211. By setting the thickness of the inorganic material layer 212 to be greater than the thickness of the metal layer 211, it is helpful to increase a transmissivity of the polarization structure for the first linear polarized light and improve a polarization degree of light passing through the polarization structure. The polarization degree may be calculated from the following formula:

$$PE = ( Tr * {T}_{TM} - Tr * {T}_{TE} ) / ( Tr * {T}_{TM} + Tr * {T}_{TE} )$$

where PE is a polarization degree, T_{TM} is a transmissivity for the first linear polarized light, T_{TE} is a transmissivity for the second linear polarized light, and Tr is a transmissivity for the natural light, that is, a ratio of the exit light to a total amount of light.

In an embodiment, as shown in FIG. 1, the wire grid 21 includes a metal layer 211 and an inorganic material layer 212 located on a side of the metal layer 211 away from the second semiconductor layer 12; and the low refraction layer 40 is located between the second semiconductor layer 12 and the polarization structure 20. A thickness of the inorganic material layer 212 is greater than a thickness of the low refraction layer 40. With such a configuration, it is helpful to increase a transmissivity of the polarization structure for the first linear polarized light and improve a polarization degree of light passing through the polarization structure.

To improve a transmissivity of the light emitting chip for the first linear polarized light and a polarization degree of the exit light, in the embodiments of the present application, parameters of some film layers of the light emitting chip shown in FIG. 1 and FIG. 2 are simulated. A structure selected for the simulation includes a second semiconductor layer, a planar light source disposed in the second semiconductor layer, a low refraction layer and a polarization structure located on a side of the second semiconductor layer. The low refraction layer is located between the polarization structure and the second semiconductor layer, and the polarization structure includes a plurality of periodically arranged wire grids. Each wire grid includes a metal layer and an inorganic material layer. A material for the metal layer is aluminum. A material for the inorganic material layer is SiO₂, and a refractive index of SiO₂ is 1.5. Parameters that can be optimized include: a period/pitch and a wire width of the wire grid, a thickness of the metal layer, a thickness of the inorganic material layer, a thickness and a refractive index of the low refraction layer. Processes of optimizing the parameters will be described in detail below.

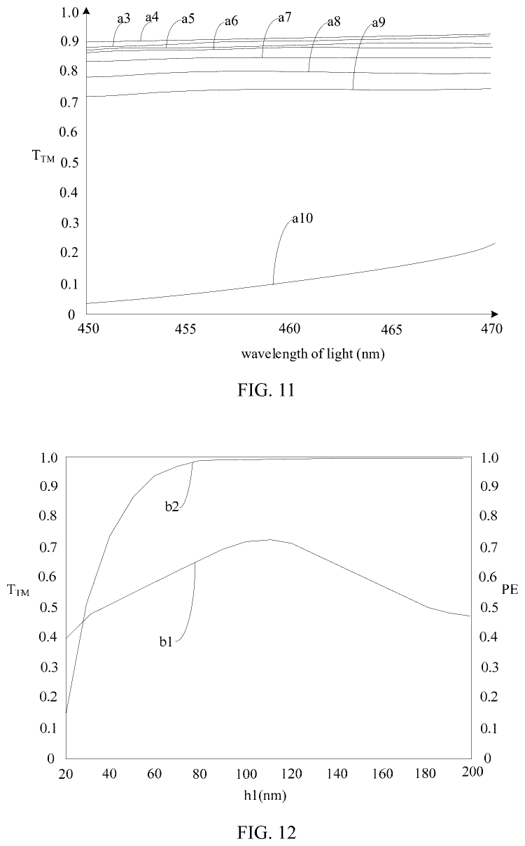

A process of optimizing the period of the wire grid is as follows: the thickness of the metal layer is set to be 100 nm; the thickness of the inorganic material layer is set to be 180 nm; the low refraction layer is not taken into consideration; and the width w of the wire grid is half of the period p of the wire grid. The period of the wire grid takes a plurality of values in a range of 10 nm˜300 nm with an interval/step of 10 nm. Each value is simulated to obtain curve graphs shown in FIG. 10 and FIG. 11. FIG. 10 is curve graphs showing relationships of a transmissivity for a first linear polarized light and a polarization degree of exit light with a period of a wire grid. In FIG. 10, a wavelength of light is 460 nm; curve a1 is a curve showing a relationship between the transmissivity T_{TM} of the first linear polarized light and the period p of the wire grid, and curve a2 is a curve showing a relationship between the polarization degree PE of the exit light and the period p of the wire grid. FIG. 11 is curve graphs showing a relationship between a transmissivity for first linear polarized light and a wavelength of light. In FIG. 11, curve a3 is a curve showing a relationship between the transmissivity T_{TM} of the first linear polarized light and the wavelength of the light when a period p of a wire grid is equal to 10 nm; curve a4 is a curve showing a relationship between the transmissivity T_{TM} of the first linear polarized light and the wavelength of the light when the period p of the wire grid is equal to 50 nm; curve a5 is a curve showing a relationship between the transmissivity T_{TM} of the first linear polarized light and the wavelength of the light when the period p of the wire grid is equal to 100 nm; curve a6 is a curve showing a relationship between the transmissivity T_{TM} of the first linear polarized light and the wavelength of the light when the period p of the wire grid is equal to 120 nm; curve a7 is a curve showing a relationship between the transmissivity T_{TM} of the first linear polarized light and the wavelength of the light when the period p of the wire grid is equal to 160 nm; curve a8 is a curve showing a relationship between the transmissivity T_{TM} of the first linear polarized light and the wavelength of the light when the period p of the wire grid is equal to 200 nm; curve a9 is a curve showing a relationship between the transmissivity T_{TM} of the first linear polarized light and the wavelength of the light when the period p of the wire grid is equal to 250 nm; curve a10 is a curve showing a relationship between the transmissivity T_{TM} of the first linear polarized light and the wavelength of the light when the period p of the wire grid is equal to 300 nm.

As can be seen from FIG. 10, when the period p is in a range of 20 nm˜290 nm, PE is greater than 50%; the smaller the period p is, the higher the T_{TM} is, and the higher the PE is. When the period p is less than 210 nm, TIM may reach above 80%, and the polarization degree is 98.03%; when the period p is less than 90 nm, T_{TM} may reach above 90%, and PE may reach 99.96%; when the period p is 40 nm, T_{TM} reaches up to 92%, and PE reaches up to 99.998%. On the premise of being processable and stable mass production, a smaller period may be selected, so that both T_{TM} and PE are higher. As can be seen from FIG. 11, when the value of the period p is a constant value, T_{TM} does not change significantly as the wavelength of the light changes, from which, it can be known that T_{TM} is not sensitive to the wavelength of the light and a color gamut of the light emitting chip does not undergo color cast or color shift due to the provision of the polarization structure.

Considering FIG. 10 and FIG. 11 comprehensively, it is determined that the period of the wire grid is in a range of 40 nm˜200 nm, and the period of the wire grid has an optimal value of 120 nm.

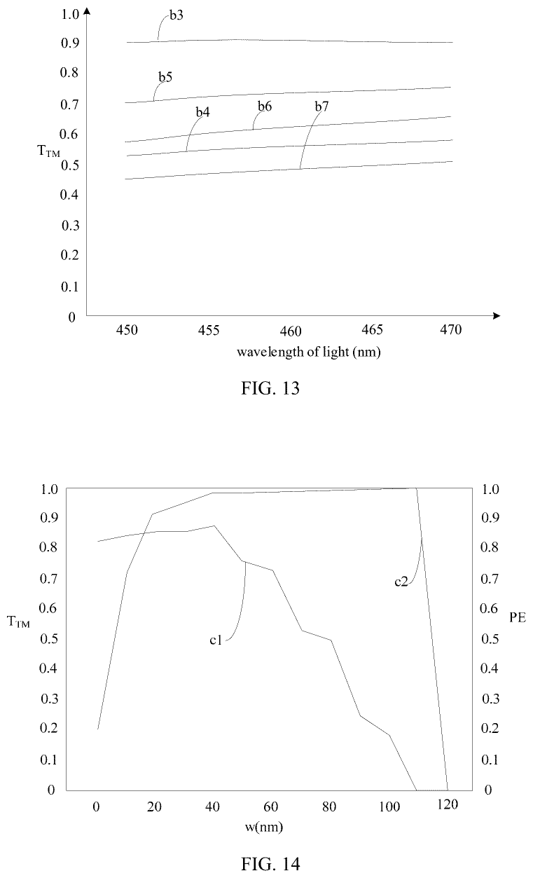

A process of optimizing the thickness of the metal layer is as follows: the period p of the wire grid is set to be 120 nm; the width of the wire grid is set to be 60 nm; the thickness of the inorganic material layer is set to be 60 nm; the low refraction layer is not taken into consideration. The thickness of the metal layer takes a plurality of values in a range of 20 nm˜200 nm with an interval/step of 10 nm, and each value is simulated to obtain curve graphs shown in FIG. 12 and FIG. 13. FIG. 12 is curve graphs showing relationships of a transmissivity for first linear polarized light and a polarization degree of exit light with a thickness of a metal layer. In FIG. 12, a wavelength of light is 460 nm; curve b1 is a curve showing a relationship between the transmissivity T_{TM} for the first linear polarized light and the thickness h1 of the metal layer, and curve b2 is a curve showing a relationship between the polarization degree PE of the exit light and the thickness h1 of the metal layer. FIG. 13 is a curve graph showing a relationship between a transmissivity for first linear polarized light and a wavelength of light. In FIG. 13, curve b3 is a curve showing a relationship between the transmissivity T_{TM} of the first linear polarized light and the wavelength of the light when a thickness h1 of a metal layer is equal to 0 nm; curve b4 is a curve showing a relationship between the transmissivity T_{TM} of the first linear polarized light and the wavelength of the light when the thickness h1 of the metal layer is equal to 50 nm; curve b5 is a curve showing a relationship between the transmissivity T_{TM} of the first linear polarized light and the wavelength of the light when the thickness h1 of the metal layer is equal to 110 nm; curve b6 is a curve showing a relationship between the transmissivity T_{TM} of the first linear polarized light and the wavelength of the light when the thickness h1 of the metal layer is equal to 150 nm; curve b7 is a curve showing a relationship between the transmissivity T_{TM} of the first linear polarized light and the wavelength of the light when the thickness h1 of the metal layer is equal to 200 nm.

As can be seen from FIG. 12 and FIG. 13, when the wavelength of the light is 460 nm, T_{TM} changes as the thickness h1 of the metal layer changes. When the thickness h1 of the metal layer is 110 nm, T_{TM} reaches about a maximum value 70%; when the thickness h1 of the metal layer is too large or too small, T_{TM} decreases, and a minimum value of T_{TM} is close to 40%. When T_{TM} reaches the maximum value, PE is 99.8%; when the thickness h1 of the metal layer is greater than 80 nm, PE is above 99%; when the thickness of the metal layer is a constant value, T_{TM} does not change significantly as the wavelength of the light changes.

Considering FIG. 12 and FIG. 13 comprehensively, it is determined that the thickness h1 of the metal layer is in a range of 60 nm˜160 nm, and the thickness h1 of the metal layer has an optimal value of 110 nm.

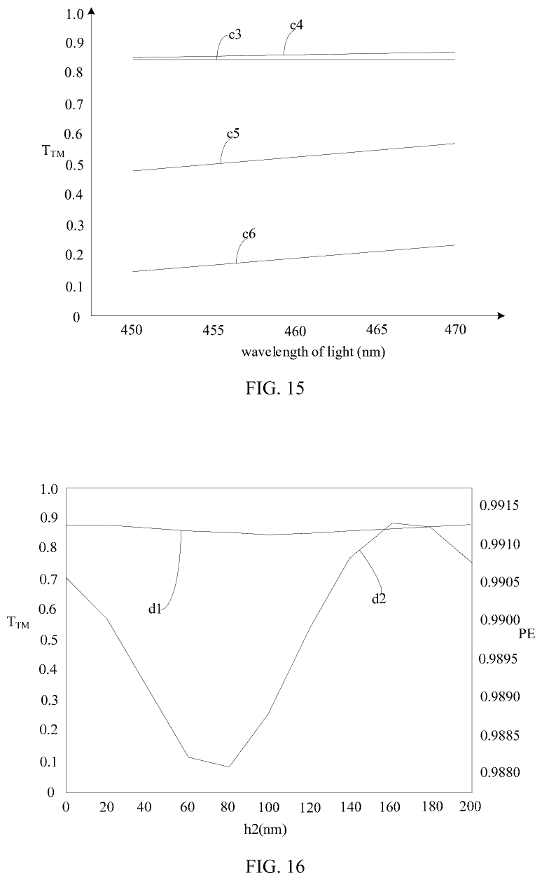

A process of optimizing the width of the wire grid is as follows: the thickness of the metal layer is set to be 110 nm; the thickness of the inorganic material layer is set to be 60 nm; the period p of the wire grid is set to be 120 nm; the low refraction layer is not taken into consideration. The width w of the wire grid takes a plurality of values in a range of 0 nm˜120 nm, with an interval/step of 10 nm. Each value is simulated to obtain curve graphs shown in FIG. 14 and FIG. 15. FIG. 14 is curve graphs showing relationships of a transmissivity for first linear polarized light and a polarization degree of exit light with a width of a wire grid. In FIG. 14, a wavelength of light is 460 nm; curve c1 is a curve showing a relationship between the transmissivity T_{TM} for the first linear polarized light and the width w of the wire grid, and curve c2 is a curve showing a relationship between the polarization degree PE of the exit light and the width w of the wire grid. FIG. 15 is curve graphs showing a relationship between a transmissivity for first linear polarized light and a wavelength of light. In FIG. 15, curve c3 is a curve showing a relationship between the transmissivity T_{TM} of the first linear polarized light and the wavelength of the light when a width w of a wire grid is equal to 10 nm; curve c4 is a curve showing a relationship between the transmissivity T_{TM} of the first linear polarized light and the wavelength of the light when the width w of the wire grid is equal to 40 nm; curve c5 is a curve showing a relationship between the transmissivity T_{TM} of the first linear polarized light and the wavelength of the light when the width w of the wire grid is equal to 70 nm; curve a6 is a curve showing a relationship between the transmissivity TIM of the first linear polarized light and the wavelength of the light when the width w of the wire grid is equal to 100 nm.

As can be seen from FIG. 14, when the width w of the wire grid is less than 40 nm, T_{TM} increases as the width w of the wire grid increases. When the width w of the wire grid is 40 nm, T_{TM} reaches a maximum value 86.89%; when the width w of the wire grid is greater than 40 nm, T_{TM} decreases as the width w of the wire grid increases; when the width w of the wire grid is close to the period of the wire grid, T_{TM} decreases to 0. When the width w of the wire grid is greater than or equal to 40 nm, PE may reach above 98.7%; when the width w of the wire grid is less than 40 nm, PE decreases as the width w of the wire grid decreases. As can be known from FIG. 15, when the width of the wire grid is a constant value, T_{TM} does not change significantly as the wavelength of the light changes.

Considering FIG. 14 and FIG. 15 comprehensively, it is determined that the width of the wire grid is in a range of 10 nm˜70 nm, and the width of the wire grid has an optimal value of 40 nm.

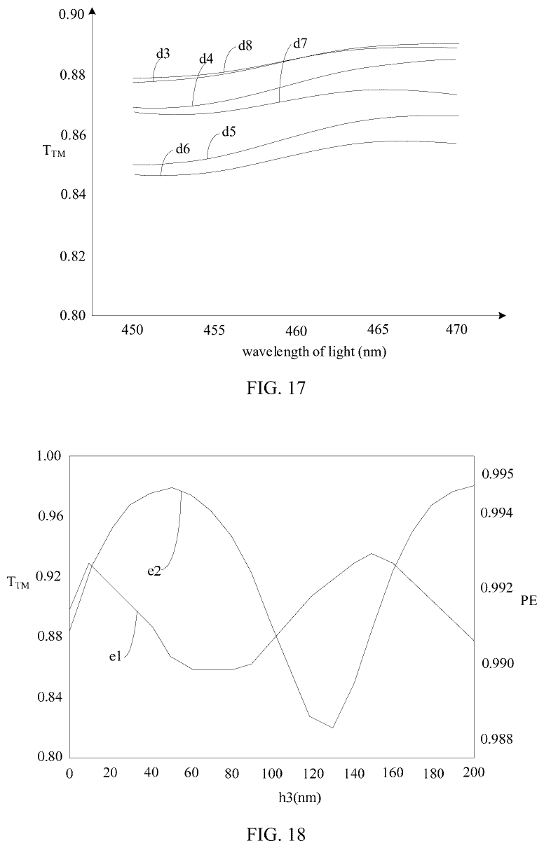

A process of optimizing the thickness of the inorganic material layer is as follows: the thickness of the metal layer is set to be 110 nm; the width w of the wire grid is set to be 40 nm (both a width of the metal layer and a width of the inorganic material layer are set to be 40 nm); the period p of the wire grid is set to be 120 nm; the low refraction layer is not taken into consideration. The thickness h2 of the inorganic material layer takes a plurality of values in a range of 0 nm˜200 nm, with an interval/step of 20 nm. Each value is simulated to obtain curve graphs shown in FIG. 16 and FIG. 17. FIG. 16 is curve graphs showing relationships of a transmissivity for first linear polarized light and a polarization degree of exit light with a thickness of an inorganic material layer. In FIG. 16, a wavelength of light is 460 nm; curve d1 is a curve showing a relationship between the transmissivity T_{TM} of the first linear polarized light and the thickness h2 of the inorganic material layer, and curve d2 is a curve showing a relationship between the polarization degree PE of the exit light and the thickness h2 of the inorganic material layer. FIG. 17 is a curve graph showing a relationship between a transmissivity for first linear polarized light and a wavelength of light. In FIG. 17, curve d3 is a curve showing a relationship between the transmissivity T_{TM} of the first linear polarized light and the wavelength of the light when a thickness h2 of an inorganic material layer is equal to 0 nm; curve d4 is a curve showing a relationship between the transmissivity T_{TM} of the first linear polarized light and the wavelength of the light when the thickness h2 of the inorganic material layer is equal to 40 nm; curve d5 is a case showing a relationship between the transmissivity T_{TM} of the first linear polarized light and the wavelength of the light when the thickness h2 of the inorganic material layer is equal to 80 nm; curve d6 is a curve showing a relationship between the transmissivity TIM of the first linear polarized light and the wavelength of the light when the thickness h2 of the inorganic material layer is equal to 120 nm; curve d7 is a curve showing a relationship between the transmissivity T_{TM} of the first linear polarized light and the wavelength of the light when the thickness h2 of the inorganic material layer is equal to 160 nm; curve d8 is a curve showing a relationship between the transmissivity T_{TM} of the first linear polarized light and the wavelength of the light when the thickness h2 of the inorganic material layer is equal to 200 nm.

As can be seen from FIG. 16, the thickness h2 of the inorganic material layer is in a range of 0 nm˜200 nm; as the thickness h2 of the inorganic material layer changes, T_{TM} does not change substantially and is below 85%, and PE does not change much and is substantially between 98.8%˜99.2%. When the thickness h2 of the inorganic material layer is 0 nm, that is, when the wire grid does not include the inorganic material layer, T_{TM} is 88.5%, and PE is 99.1%; when the thickness h2 of the inorganic material layer is 200 nm, T_{TM} is 88.4%, and PE is 99.1%. That is, in two cases where the wire grid does not include the inorganic material layer and the thickness h2 of the inorganic material layer is 200 nm, a difference in T_{TM} is relatively small, and PE is same. As can be seen from FIG. 17, when the thickness h2 of the inorganic material layer is constant, TIM does not change significantly as the wavelength of the light changes.

Considering FIG. 16 and FIG. 17 comprehensively, it is determined that the wire grid does not include the inorganic material layer, or the wire grid includes the inorganic material layer, the thickness of the inorganic material layer is in a range of 120 nm˜200 nm, and the thickness of the inorganic material layer has an optimal value of 200 nm.

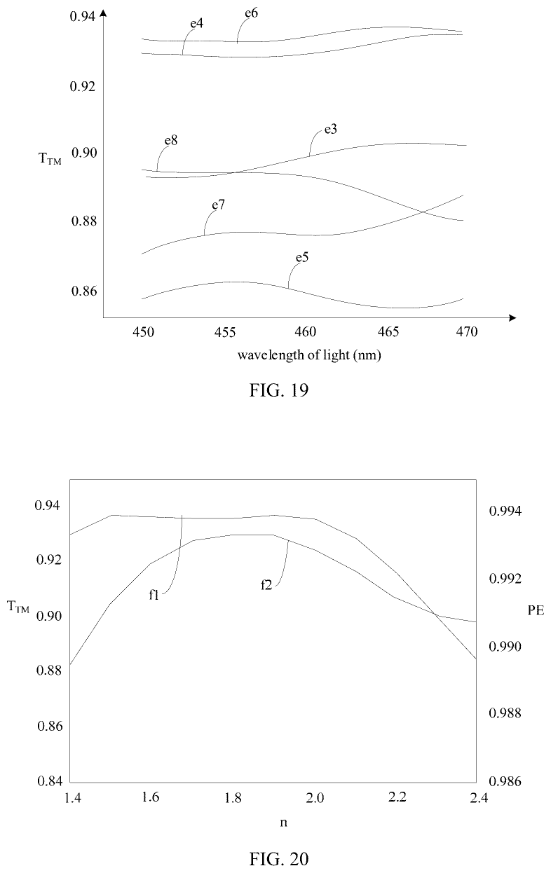

A process of optimizing the thickness of the low refraction layer is as follows: the thickness of the metal layer is set to be 110 nm; the thickness of the inorganic material layer is set to be 200 nm; the width of the wire grid is set to be 40 nm (both a width of the metal layer and a width of the inorganic material layer are set to be 40 nm); the period of the wire grid is set to be 120 nm; the refractive index of the low refraction layer is set to be 1.5. The thickness h3 of the low refraction layer takes a plurality of values in a range of 0 nm˜200 nm, with an interval/step of 10 nm, and each value is simulated to obtain curve graphs shown in FIG. 18 and FIG. 19. FIG. 18 is curve graphs showing relationships of a transmissivity for first linear polarized light and a polarization degree of exit light with a thickness of a low refraction layer. In FIG. 18, a wavelength of light is 460 nm; curve e1 is a curve showing a relationship between the transmissivity T_{TM} of the first linear polarized light and the thickness h3 of the low refraction layer, and curve e2 is a curve showing a relationship between the polarization degree PE of the exit light and the thickness h3 of the low refraction layer. FIG. 19 is curve graphs showing a relationship between a transmissivity for first linear polarized light and a wavelength of light. In FIG. 19, curve e3 is a curve showing a relationship between the transmissivity T_{TM} of the first linear polarized light and the wavelength of the light when a thickness h3 of a low refraction layer is equal to 0 nm; curve e4 is a curve showing a relationship between the transmissivity T_{TM} of the first linear polarized light and the wavelength of the light when the thickness h3 of the low refraction layer is equal to 10 nm; curve e5 is a curve showing a relationship between the transmissivity T_{TM} of the first linear polarized light and the wavelength of the light when the thickness h3 of the low refraction layer is equal to 70 nm; curve e6 is a curve showing a relationship between the transmissivity T_{TM} of the first linear polarized light and the wavelength of the light when the thickness h3 of the low refraction layer is equal to 150 nm; curve e7 is a curve showing a relationship between the transmissivity T_{TM} of the first linear polarized light and the wavelength of the light when the thickness h3 of the low refraction layer is equal to 200 nm; curve e8 is a curve showing a relationship between the transmissivity T_{TM} of the first linear polarized light and the wavelength of the light when the thickness h3 of the low refraction layer is equal to 110 nm.

As can be seen from FIG. 18, when the thickness h3 of the low refraction layer is 0, that is, when the light emitting chip does not include the low refraction layer, T_{TM} is 90%; when the light emitting chip includes the low refraction layer, TIM changes nonlinearly as the thickness h3 of the low refraction layer changes, and when the thickness h3 of the low refraction layer is 10 nm and 150 nm, T_{TM} reaches about a maximum value 93%; as the thickness h3 of the low refraction layer changes, PE does not change much and is about 99%. As can be seen from FIG. 19, when the light emitting chip does not include the low refraction layer, and when the light emitting chip includes the low refraction layer and the thickness of the low refraction layer is a constant value, T_{TM} does not change much as the wavelength of the light changes, and a value of the thickness h3 of the low refraction layer may be determined according to a wavelength of light emitted from the light emitting chip. In a blue light band, when the thickness h3 of the low refraction layer is 10 nm and 150 nm, T_{TM} is about 90%, and PE is about 99%.

Considering FIG. 18 and FIG. 19 comprehensively, it is determined that the thickness h3 of the low refraction layer is in a range of 0 nm˜40 nm or 120 nm˜180 nm, and the thickness h3 of the low refraction layer has an optimal value of 10 nm or 150 nm.

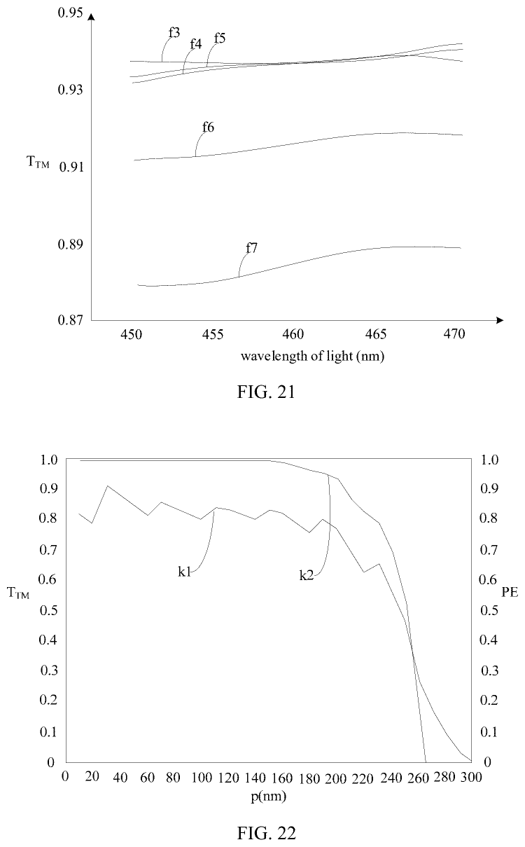

A process of optimizing the refractive index of the low refraction layer is as follows: the thickness of the metal layer is set to be 110 nm; the thickness of the inorganic material layer is set to be 200 nm; the width of the wire grid is set to be 40 nm (both a width of the metal layer and a width of the inorganic material layer are set to be 40 nm); the period of the wire grid is set to be 120 nm; the refractive index of the second semiconductor layer is set to be 2.4; the thickness of the low refraction layer is set to be 150 nm. The refractive index n of the low refraction layer takes a plurality of values in a range of 1.4˜2.4, with an interval/step of 0.1. Each value is simulated to obtain curve graphs shown in FIG. 20 and FIG. 21. FIG. 20 is curve graphs showing relationships of a transmissivity for first linear polarized light and a polarization degree of exit light with a refractive index of a low refraction layer. In FIG. 20, a wavelength of light is 460 nm; curve f1 is a curve showing a relationship between the transmissivity TIM of the first linear polarized light and the refractive index n of the low refraction layer, and curve f2 is a curve showing a relationship between the polarization degree PE of the exit light and the refractive index n of the low refraction layer. FIG. 21 is curve graphs showing a relationship between a transmissivity for first linear polarized light and a wavelength of light. In FIG. 21, curve f3 is a curve showing a relationship between the transmissivity T_{TM} of the first linear polarized light and the wavelength of the light when a refractive index n of a low refraction layer is equal to 1.5; curve f4 is a curve showing a relationship between the transmissivity T_{TM} of the first linear polarized light and the wavelength of the light when the refractive index n of the low refraction layer is equal to 1.7; curve f5 is a curve showing a relationship between the transmissivity T_{TM} of the first linear polarized light and the wavelength of the light when the refractive index n of the low refraction layer is equal to 1.9; curve f6 is a curve showing a relationship between the transmissivity T_{TM} of the first linear polarized light and the wavelength of the light when the refractive index n of the low refraction layer is equal to 2.2; curve f7 is a curve showing a relationship between the transmissivity T_{TM} of the first linear polarized light and the wavelength of the light when the refractive index n of the low refraction layer is equal to 2.4.

As can be seen from FIG. 20 and FIG. 21, when the refractive index n of the low refraction layer changes between 1.5˜2.0, T_{TM} is greater than 93%, and PE is greater than 99%; when the refractive index n of the low refraction layer is 2.4, that is, when the refractive index of the low refraction layer is the same as the refractive index of the second semiconductor layer, a maximum value of T_{TM} is about 88%, and PE is 99%. When the refractive index n of the low refraction layer is greater than 2.1, compared with the refractive index n of the low refraction layer between 1.5˜2.0, T_{TM} decreases, and PE does not change much.

Considering FIG. 20 and FIG. 21 comprehensively, it is determined that the refractive index n of the low refraction layer is in a range of 1.5˜2.0.

The above processes of optimizing parameters are performed for a light emitting chip with a light emitting color being blue (the range of the wavelength of the light is 460 nm). The optimal values of the parameters are applied to the light emitting chip, and by analyzing T_{TM} and PE of light in a visible light range (450 nm-750 nm), it can be known that, in the visible light range, T_{TM} is greater than 84%, PE is greater than 99%, an absorptivity for the first linear polarized light is about 5%, and a light loss is about 11%; the transmissivity for the second linear polarized light is about 0, an absorptivity for the second linear polarized light is 20%, and a reflectance/reflectivity for the second linear polarized light is about 80%. It can be known that, in the entire visible light range, the exit light is the first linear polarized light, where the transmissivity for the light is 42%, the absorptivity for the light is about 12.5%, and the reflectance/reflectivity for the light is about 45.5%. That is, in the entire visible light range, about 12.5% of light is absorbed and thus lost by the polarization structure, 45.5% of light is reflected by the polarization structure, and the light reflected by the polarization structure is converted by the auxiliary structure into light including the first linear polarized light, where the first linear polarized light exits through the polarization structure.

With reference to the above simulation results, to improve the transmissivity of the light emitting chip shown in FIG. 1 (the wire grid 21 includes a metal layer 211 and an inorganic material layer 212 located on a side of the metal layer 211 facing the second semiconductor layer 12, the metal layer 211 is in direct contact with the low refraction layer 40, and the low refraction layer 40 is located between the second semiconductor layer 12 and the polarization structure 20) for the first linear polarized light and the polarization degree of the exit light, the period of the wire grid may be set to be in a range of 40 nm˜200 nm, the width of the wire grid may be set to be in a range of 10 nm˜70 nm, the thickness of the metal layer may be set to be in a range of 60 nm˜160 nm, the thickness of the inorganic material layer may be set to be in a range of 120 nm˜200 nm, and the thickness of the low refraction layer may be set to be in a range of 0 nm˜40 nm or 120 nm˜180 nm.

Further, the period of the wire grid is 120 nm, and the width of the wire grid is 40 nm; the material for the metal layer is aluminum, and the thickness of the metal layer is 110 nm; the thickness of the low refraction layer is 150 nm, and the refractive index of the low refraction layer is 1.9; the material for the inorganic material layer is SiO₂, and the thickness of the inorganic material layer is 200 nm. With such a configuration, the transmissivity of the light emitting chip for the first linear polarized light is 93.6%, the polarization degree of the exit light is 99.3%, and the transmissivity for the natural light is 46.9%.

With reference to the above simulation results, to improve the transmissivity of the light emitting chip shown in FIG. 2 (the low refraction layer 40 is located between the second semiconductor layer 12 and the polarization structure 20, the wire grid 21 includes only a metal layer 211, and the metal layer 211 is in direct contact with the low refraction layer 40) for the first linear polarized light and the polarization degree of the exit light, the period of the wire grid may be set to be in a range of 40 nm˜200 nm, the width of the wire grid may be set to be in a range of 10 nm˜70 nm, the thickness of the metal layer may be set to be in a range of 60 nm˜160 nm, and the thickness of the low refraction layer may be set to be in a range of 0 nm˜40 nm or 120 nm˜180 nm.

To improve a transmissivity of the light emitting chip for the first linear polarized light and a polarization degree of the exit light, in the embodiments of the present application, parameters of some film layers of the light emitting chip shown in FIG. 3 to FIG. 6 are simulated. A structure selected for the simulation includes a second semiconductor layer, a planar light source disposed in the second semiconductor layer, an organic layer, a low refraction layer and a polarization structure located on a side of the second semiconductor layer. The polarization structure includes a plurality of periodically arranged wire grids; each wire grid includes a metal layer and an inorganic material layer, and a material for the metal layer is aluminum; a material for the inorganic material layer is SiO₂, and a refractive index of SiO₂ is 1.5; a material for the organic layer is organic resin, and a refractive index of the organic layer is 1.49. Parameters that can be optimized include: a period and a wire width of the wire grid, a thickness of the metal layer, a thickness of the inorganic material layer, a thickness and a refractive index of the low refraction layer. Processes of optimizing the parameters will be described in detail below.

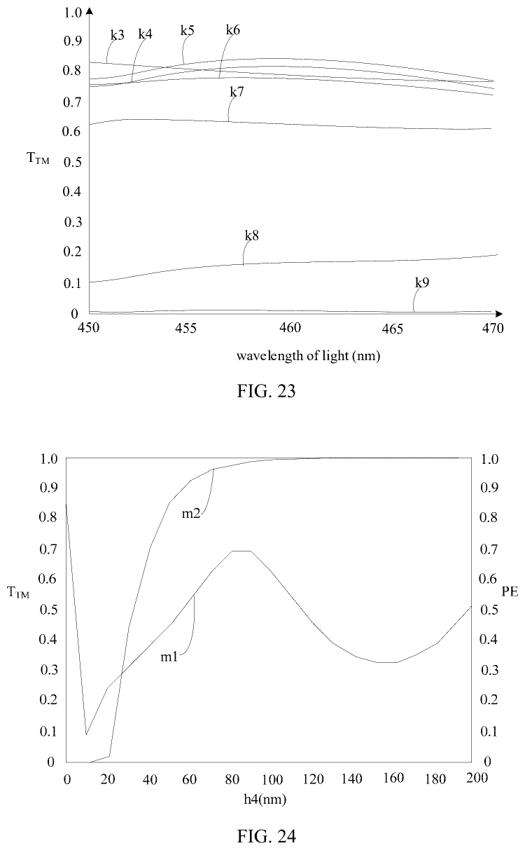

A process of optimizing the period of the wire grid is as follows: the thickness of the metal layer is set to be 100 nm; the wire grid does not include an inorganic material layer; the low refraction layer is not taken into consideration; the organic layer includes only organic structures located between adjacent wire grids; the width w of the wire grid is half of the period p of the wire grid. The period of the wire grid takes a plurality of values in a range of 10 nm˜300 nm, with an interval/step of 10 nm, and each value is simulated to obtain curve graphs shown in FIG. 22 and FIG. 23. FIG. 22 is curve graphs showing relationships of a transmissivity for first linear polarized light and a polarization degree of exit light with a period of a wire grid. In FIG. 22, a wavelength of light is 460 nm; curve k1 is a curve showing a relationship between the transmissivity T_{TM} of the first linear polarized light and the period p of the wire grid, and curve k2 is a curve showing a relationship between the polarization degree PE of the exit light and the period p of the wire grid. FIG. 23 is curve graphs showing a relationship between a transmissivity for first linear polarized light and a wavelength of light. In FIG. 23, curve k3 is a curve showing a relationship between the transmissivity T_{TM} of the first linear polarized light and the wavelength of the light when a period p of a wire grid is equal to 20 nm; curve k4 is a curve showing a relationship between the transmissivity T_{TM} of the first linear polarized light and the wavelength of the light when the period p of the wire grid is equal to 120 nm; curve k5 is a curve showing a relationship between the transmissivity T_{TM} of the first linear polarized light and the wavelength of the light when the period p of the wire grid is equal to 70 nm; curve k6 is a curve showing a relationship between the transmissivity T_{TM} of the first linear polarized light and the wavelength of the light when the period p of the wire grid is equal to 170 nm; curve k7 is a curve showing a relationship between the transmissivity T_{TM} of the first linear polarized light and the wavelength of the light when the period p of the wire grid is equal to 220 nm; curve k8 is a curve showing a relationship between the transmissivity TIM of the first linear polarized light and the wavelength of the light when the period p of the wire grid is equal to 270 nm; curve k9 is a curve showing a relationship between the transmissivity T_{TM} of the first linear polarized light and the wavelength of the light when the period p of the wire grid is equal to 200 nm.

As can be seen from FIG. 22 and FIG. 23, when the period p is below 190 nm, T_{TM} is about 80%, and PE is about 95%; when the period p is less than 120 nm, T_{TM} may reach above 80%, and the polarization degree reaches above 99%; when the period p is less than 40 nm, T_{TM} may reach above 80%, and PE may reach 99.996%. On the premise of being processable and stable mass production, a relatively small period may be selected, so that both T_{TM} and PE are relatively high.

Considering FIG. 22 and FIG. 23 comprehensively, it is determined that the period of the wire grid is in a range of 40 nm˜200 nm, and the period of the wire grid has an optimal value of 120 nm.

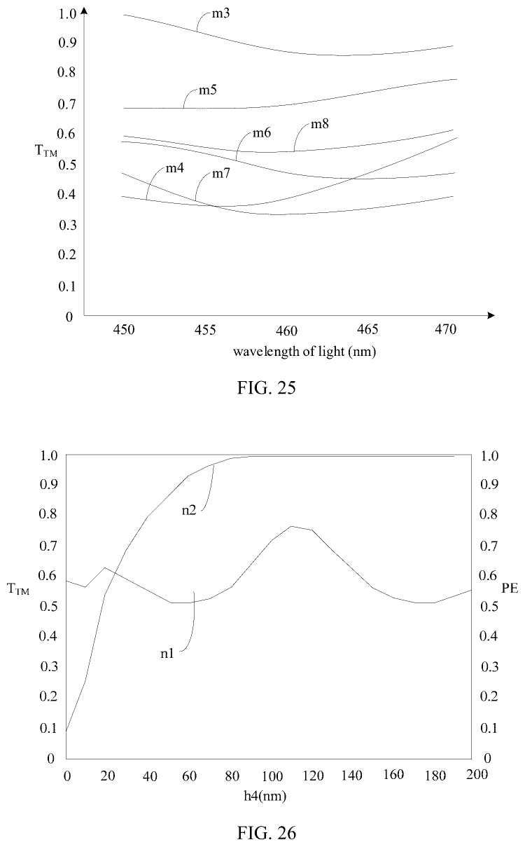

When the wire grid does not include an inorganic material layer, a process of optimizing the thickness of the metal layer is as follows: the period p of the wire grid is set to be 120 nm; the width of the wire grid is set to be 60 nm; the wire grid does not include an inorganic material layer; the low refraction layer is not taken into consideration; the organic layer includes only organic structures located between adjacent wire grids. The thickness of the metal layer takes a plurality of values in a range of 0 nm˜200 nm, with an interval/step of 10 nm. Each value is simulated to obtain curve graphs shown in FIG. 24 and FIG. 25. FIG. 24 is curve graphs showing relationships of a transmissivity for first linear polarized light and a polarization degree of exit light with a thickness of a metal layer. In FIG. 24, a wavelength of light is 460 nm; curve m1 is a curve showing a relationship between the transmissivity T_{TM} of the first linear polarized light and the thickness h4 of the metal layer, and curve m2 is a curve showing a relationship between the polarization degree PE of the exit light and the thickness h4 of the metal layer. FIG. 25 is curve graphs showing a relationship between a transmissivity for first linear polarized light and a wavelength of light. In FIG. 25, curve m3 is a curve showing a relationship between the transmissivity T_{TM} of the first linear polarized light and the wavelength of the light when a thickness h4 of a metal layer is equal to 0 nm; curve m4 is a curve showing a relationship between the transmissivity TIM of the first linear polarized light and the wavelength of the light when the thickness h4 of the metal layer is equal to 40 nm; curve m5 is a curve showing a relationship between the transmissivity T_{TM} of the first linear polarized light and the wavelength of the light when the thickness h4 of the metal layer is equal to 80 nm; curve m6 is a curve showing a relationship between the transmissivity T_{TM} of the first linear polarized light and the wavelength of the light when the thickness h4 of the metal layer is equal to 120 nm; curve m7 is a curve showing a relationship between the transmissivity T_{TM} of the first linear polarized light and the wavelength of the light when the thickness h4 of the metal layer is equal to 160 nm; curve m8 is a curve showing a relationship between the transmissivity TIM of the first linear polarized light and the wavelength of the light when the thickness h4 of the metal layer is equal to 200 nm.

As can be seen from FIG. 24 and FIG. 25, when the wire grid does not include an inorganic material layer, TIM changes nonlinearly as the thickness h4 of the metal layer changes; when the thickness h4 of the metal layer is 80 nm, T_{TM} reaches about a maximum value 70%, and PE is about 98%; when the thickness h4 of the metal layer is a constant value, as the wavelength of the light changes, TIM changes slightly with a change amplitude of about ±5%.

Considering FIG. 24 and FIG. 25 comprehensively, it is determined that, when the wire grid does not include an inorganic material layer, the thickness h4 of the metal layer is in a range of 70 nm˜90 nm, and the thickness h4 of the metal layer has an optimal value of 80 nm.

When the wire grid includes an inorganic material layer, a process of optimizing the thickness of the metal layer is as follows: the period p of the wire grid is set to be 120 nm; the width of the wire grid is set to be 60 nm; the thickness of the inorganic material layer is set to be 60 nm; the low refraction layer is not taken into consideration; the organic layer includes only organic structures located between adjacent wire grids. The thickness of the metal layer takes a plurality of values in a range of 0 nm˜200 nm with an interval/step of 10 nm. Each value is simulated to obtain curve graphs shown in FIG. 26 and FIG. 27. FIG. 26 is curve graphs showing relationships of a transmissivity for first linear polarized light and a polarization degree of exit light with a thickness of a metal layer. In FIG. 26, a wavelength of light is 460 nm; curve n1 is a curve showing a relationship between the transmissivity T_{TM} of the first linear polarized light and the thickness h4 of the metal layer, and curve n2 is a curve showing a relationship between the polarization degree PE of the exit light and the thickness h4 of the metal layer. FIG. 27 is curve graphs showing a relationship between a transmissivity for first linear polarized light and a wavelength of light. In FIG. 27, curve n3 is a curve showing a relationship between the transmissivity TIM of the first linear polarized light and the wavelength of the light when a thickness h4 of a metal layer is equal to 10 nm; curve n4 is a curve showing a relationship between the transmissivity TIM of the first linear polarized light and the wavelength of the light when the thickness h4 of the metal layer is equal to 60 nm; curve n5 is a curve showing a relationship between the transmissivity T_{TM} of the first linear polarized light and the wavelength of the light when the thickness h4 of the metal layer is equal to 110 nm; curve n6 is a curve showing a relationship between the transmissivity T_{TM} of the first linear polarized light and the wavelength of the light when the thickness h4 of the metal layer is equal to 160 nm; curve n7 is a curve showing a relationship between the transmissivity T_{TM} of the first linear polarized light and the wavelength of the light when the thickness h4 of the metal layer is equal to 200 nm.

As can be seen from FIG. 26 and FIG. 27, when the wire grid includes an inorganic material layer, TIM changes nonlinearly as the thickness h4 of the metal layer changes; when the thickness h4 of the metal layer is 110 nm, T_{TM} reaches about a maximum value 76%, and PE is about 99.88%; when the thickness h4 of the metal layer is greater than 80 nm, PE is greater than 99%; when the thickness h4 of the metal layer is a constant value, TIM changes slightly as the wavelength of the light changes.

Considering FIG. 26 and FIG. 27 comprehensively, it is determined that the thickness h4 of the metal layer is in a range of 100 nm˜120 nm, and the thickness h4 of the metal layer has an optimal value of 110 nm.

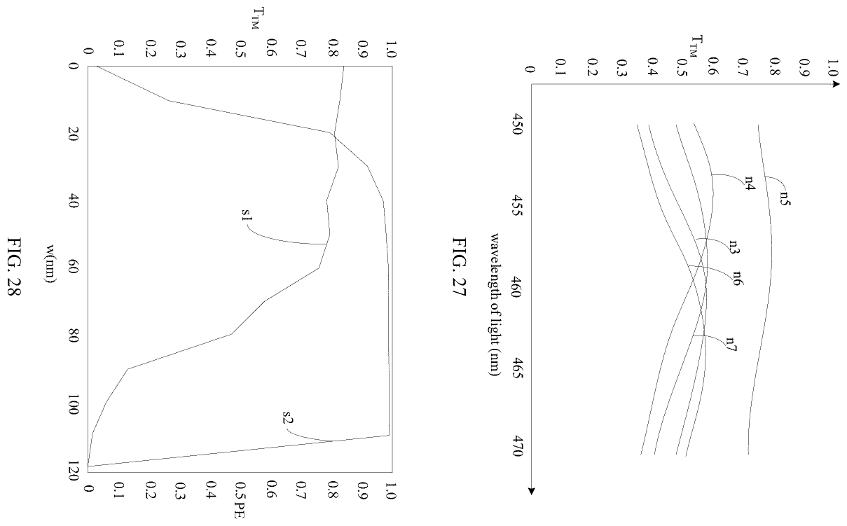

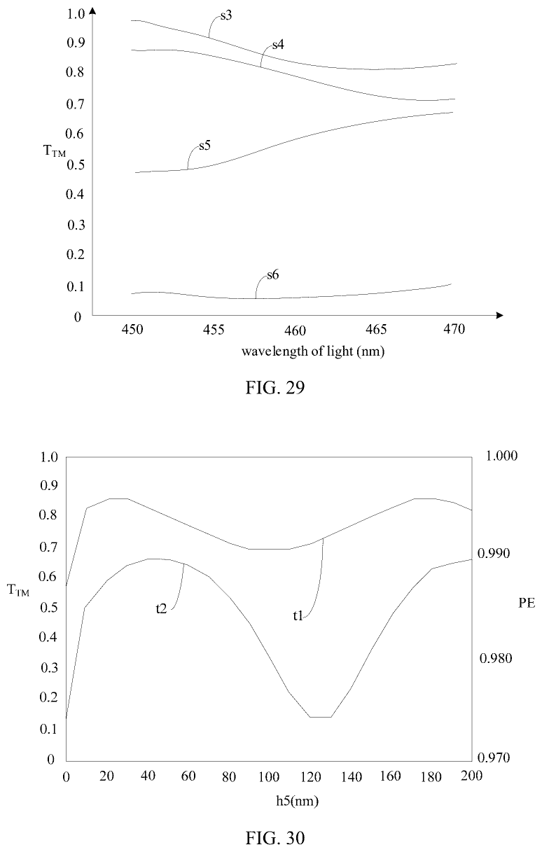

A process of optimizing the width of the wire grid is as follows: the thickness of the metal layer is set to be 110 nm; the thickness of the inorganic material layer is set to be 60 nm; the low refraction layer is not taken into consideration; the period p of the wire grid is set to be 120 nm; the organic layer includes only organic structures located between adjacent wire grids. The width w of the wire grid takes a plurality of values in a range of 0 nm˜120 nm, with an interval/step of 10 nm. Each value is simulated to obtain curve graphs shown in FIG. 28 and FIG. 29. FIG. 28 is curve graphs showing relationships of a transmissivity for first linear polarized light and a polarization degree of exit light with a width of a wire grid. In FIG. 28, a wavelength of light is 460 nm; curve s1 is a curve showing a relationship between the transmissivity T_{TM} of the first linear polarized light and the width w of the wire grid, and curve s2 is a curve showing a relationship between the polarization degree PE of the exit light and the width w of the wire grid. FIG. 29 is curve graphs showing a relationship between a transmissivity for first linear polarized light and a wavelength of light. In FIG. 29, curve s3 is a curve showing a relationship between the transmissivity T_{TM} of the first linear polarized light and the wavelength of the light when a width w of a wire grid is equal to 10 nm; curve s4 is a curve showing a relationship between the transmissivity TIM of the first linear polarized light and the wavelength of the light when the width w of the wire grid is equal to 40 nm; curve s5 is a curve showing a relationship between the transmissivity T_{TM} of the first linear polarized light and the wavelength of the light when the width w of the wire grid is equal to 70 nm; curve s6 is a curve showing a relationship between the transmissivity T_{TM} of the first linear polarized light and the wavelength of the light when the width w of the wire grid is equal to 100 nm.

As can be seen from FIG. 28 and FIG. 29, the smaller the width w of the wire grid is, the higher the T_{TM} is; when the width w of the wire grid is between 40 nm˜50 nm, T_{TM} may reach about 80%, and PE is greater than 99.34%; when the width w of the wire grid is greater than 50 nm, as the width of the wire grid increases, T_{TM} rapidly decreases, and PE maintains above 99%.

Considering FIG. 28 and FIG. 29 comprehensively, it is determined that the width of the wire grid is in a range of 40 nm˜60 nm, and the width of the wire grid has an optimal value of 50 nm.

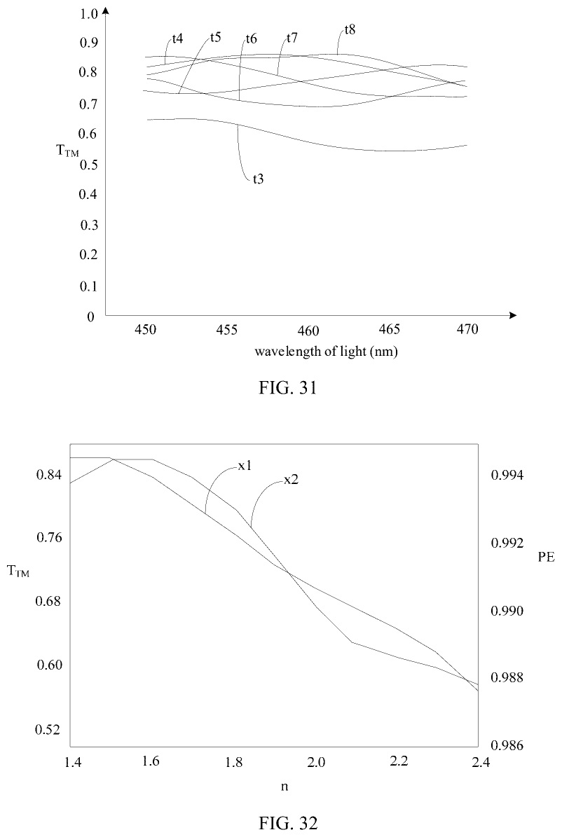

A process of optimizing the thickness of the low refraction layer is as follows: the thickness of the metal layer is set to be 110 nm; the wire grid does not include an inorganic material layer; the width of the wire grid is set to be 40 nm; the period of the wire grid is set to be 120 nm; the refractive index of the low refraction layer is set to be 1.5. The thickness h5 of the low refraction layer takes a plurality of values in a range of 0 nm˜200 nm with an interval/step of 10 nm. Each value is simulated to obtain curve graphs shown in FIG. 30 and FIG. 31. FIG. 30 is curve graphs showing relationships of a transmissivity for first linear polarized light and a polarization degree of exit light with a thickness of a low refraction layer. In FIG. 30, a wavelength of light is 460 nm; curve t1 is a curve showing a relationship between the transmissivity T_{TM} for the first linear polarized light and the thickness h5 of the low refraction layer, and curve t2 is a curve showing a relationship between the polarization degree PE of the exit light and the thickness h5 of the low refraction layer. FIG. 31 is curve graphs showing a relationship between a transmissivity for first linear polarized light and a wavelength of light. In FIG. 31, curve t3 is a curve showing a relationship between the transmissivity T_{TM} of the first linear polarized light and the wavelength of the light when a thickness h5 of a low refraction layer is equal to 0 nm; curve t4 is a curve showing a relationship between the transmissivity T_{TM} of the first linear polarized light and the wavelength of the light when a thickness h5 of a low refraction layer is equal to 20 nm; curve t5 is a curve showing a relationship between the transmissivity T_{TM} of the first linear polarized light and the wavelength of the light when the thickness h5 of the low refraction layer is equal to 60 nm; curve t6 is a curve showing a relationship between the transmissivity T_{TM} of the first linear polarized light and the wavelength of the light when the thickness h5 of the low refraction layer is equal to 100 nm; curve t7 is a curve showing a relationship between the transmissivity T_{TM} of the first linear polarized light and the wavelength of the light when the thickness h5 of the low refraction layer is equal to 140 nm; curve t8 is a curve showing a relationship between the transmissivity TIM of the first linear polarized light and the wavelength of the light when the thickness h5 of the low refraction layer is equal to 180 nm.

As can be seen from FIG. 30 and FIG. 31, when the thickness h5 of the low refraction layer is in a range of 10 nm˜30 nm or 170 nm˜190 nm, T_{TM} reaches about a maximum value 85%; when the thickness h5 of the low refraction layer is 0, that is, when the low refraction layer is not included, T_{TM} is about 58%, and PE is about 97.5%. When the light emitting chip does not include a low refraction layer, and when the light emitting chip includes a low refraction layer and the thickness of the low refraction layer is a constant value, TIM changes slightly as the wavelength of the light changes.

Considering FIG. 30 and FIG. 31 comprehensively, it is determined that the thickness h5 of the low refraction layer is in a range of 10 nm˜30 nm or 170 nm˜200 nm, and the thickness h5 of the low refraction layer has an optimal value of 20 nm or 180 nm.

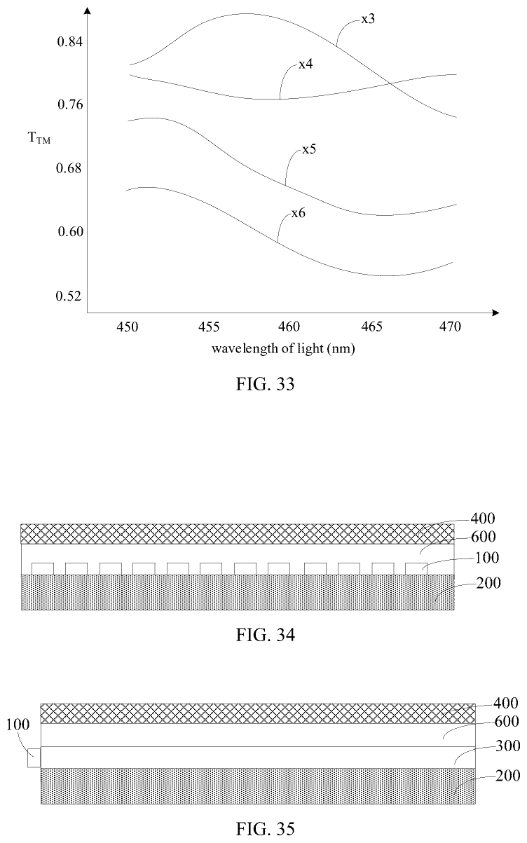

A process of optimizing the refractive index of the low refraction layer is as follows: the thickness of the metal layer is set to be 110 nm; the wire grid does not include an inorganic material layer; the width of the wire grid is set to be 40 nm; the period of the wire grid is set to be 120 nm; the refractive index of the second semiconductor layer is set to be 2.4; the thickness of the low refraction layer is set to be 180 nm. The refractive index n of the low refraction layer takes a plurality of values in a range of 1.4˜2.4 with an interval/step of 0.1. Each value is simulated to obtain curve graphs shown in FIG. 32 and FIG. 33. FIG. 32 is curve graphs showing relationships of a transmissivity for first linear polarized light and a polarization degree of exit light with a refractive index of a low refraction layer. In FIG. 32, a wavelength of light is 460 nm; curve x1 is a curve showing a relationship between the transmissivity T_{TM} of the first linear polarized light and the refractive index n of the low refraction layer, and curve x2 is a curve showing a relationship between the polarization degree PE of the exit light and the refractive index n of the low refraction layer. FIG. 33 is curve graphs showing a relationship between a transmissivity for first linear polarized light and a wavelength of light. In FIG. 33, curve x3 is a curve showing a relationship between the transmissivity T_{TM} of the first linear polarized light and the wavelength of the light when a refractive index n of a low refraction layer is equal to 1.4; curve x4 is a curve showing a relationship between the transmissivity T_{TM} of the first linear polarized light and the wavelength of the light when the refractive index n of the low refraction layer is equal to 1.8; curve x5 is a curve showing a relationship between the transmissivity T_{TM} of the first linear polarized light and the wavelength of the light when the refractive index n of the low refraction layer is equal to 2.2; curve x6 is a curve showing a relationship between the transmissivity T_{TM} of the first linear polarized light and the wavelength of the light when the refractive index n of the low refraction layer is equal to 2.4.

As can be seen from FIG. 32 and FIG. 33, as the refractive index n of the low refraction layer increases, T_{TM} decreases, and PE first increases and then decreases; when the refractive index n of the low refraction layer is 1.4 or 1.5, T_{TM} reaches a maximum value 86%, and the polarization degree is about 98.8%. Therefore, a material with a low refractive index is selected to prepare the low refraction layer, for example, SiO₂ with a refractive index of 1.5 or MgF with a refractive index of 1.38 may be selected.

Considering FIG. 32 and FIG. 33 comprehensively, it is determined that the refractive index n of the low refraction layer is less than 1.9.

If the light emitting chip includes the inorganic material layer and the organic layer, when a refractive index of the inorganic material layer is the same as or slightly different from a refractive index of the organic layer, and both of them are less than 1.9, the inorganic material layer and the organic layer have substantially the same effect on adjusting the transmissivity for the first linear polarized light and the polarization degree of the exit light. Therefore, it can be determined that, in the embodiments shown in FIG. 3, FIG. 5 and FIG. 6, a distance between a surface of the inorganic material layer away from the second semiconductor layer and a surface of the low refraction layer facing the second semiconductor layer is in a range of 170 nm to 200 nm.

With reference to the above simulation results, to improve the transmissivity of the light emitting chip shown in FIG. 4 for the first linear polarized light and the polarization degree of the exit light, the period/pitch of the wire grid may be set to be in a range of 40 nm˜200 nm, the width of the wire grid may be set to be in a range of 40 nm˜60 nm, the thickness of the metal layer may be set to be in a range of 70 nm˜90 nm, and the thickness of the low refraction layer may be set to be in a range of 10 nm˜30 nm or 170 nm˜200 nm.

Further, the period of the wire grid is less than 160 nm, a ratio of the width of the wire grid to the period of the wire grid is in a range of 33%˜42%, the thickness of the metal layer is 110 nm, the thickness of the low refraction layer is in a range of 170 nm˜190 nm, and the refractive index of the low refraction layer is in a range of 1.4˜1.5. With such a configuration, the transmissivity of the light emitting chip for the first linear polarized light is 83.15%, the polarization degree of the exit light is 99.75%, and the transmissivity for the natural light is 41.63%.

With reference to the above simulation results, to improve the transmissivity of the light emitting chip shown in FIG. 3, FIG. 5 and FIG. 6 for the first linear polarized light and the polarization degree of the exit light, the period of the wire grid may be set to be in a range of 40 nm˜200 nm, the width of the wire grid may be set to be in a range of 40 nm˜60 nm, the thickness of the metal layer may be set to be in a range of 100 nm˜120 nm, and a distance between a surface of the inorganic material layer away from the second semiconductor layer and a surface of the low refraction layer facing the second semiconductor layer may be set to be in a range of 170 nm˜200 nm.

Further, the period of the wire grid is less than 160 nm, a ratio of the width of the wire grid to the period of the wire grid is in a range of 33%˜42%, the thickness of the metal layer is 110 nm, the refractive index of the low refraction layer is in a range of 1.4˜1.5, and a distance between a surface of the inorganic material layer away from the second semiconductor layer and a surface of the low refraction layer facing the second semiconductor layer is in a range of 170 nm˜200 nm.

The above processes of optimizing parameters are performed on a light emitting chip with a light emitting color being blue (the range of the wavelength of the light is 460 nm). The optimal values of the parameters are applied to the light emitting chip, and the following results are obtained from simulation: T_{TM} in a visible light range fluctuates greatly as the wavelength changes; a wavelength of light emitted from a light emitting chip with a light emitting color being red may be set to be in a range of 640 nm˜700 nm, a wavelength of light emitted from a light emitting chip with a light emitting color being green may be set to be in a range of 500 nm˜580 nm, and a wavelength of light emitted from a light emitting chip with a light emitting color being blue is in a range of 430 nm˜490 nm, so that T_{TM} is relatively high (above 85%) and PE is relatively high (above 98.8%). In the visible light range, T_{TM} is about 80%, an absorptivity for the first linear polarized light is about 12%, and a reflectance/reflectivity for the first linear polarized light is about 8%; the transmissivity for the second linear polarized light is substantially 0, an absorptivity for the second linear polarized light is 20%, and a reflectance/reflectivity for the second linear polarized light is about 80%. It can be seen that, in the entire visible light range, the exit light is the first linear polarized light, where the transmissivity for the light is about 40%, the reflectance/reflectivity for the light is about 44%, and the absorptivity for the light is about 16%.

In an embodiment, as shown in FIG. 1 to FIG. 6, the light emitting chip further includes a reflective film layer 60 surrounding side portions of the light emitting layer 10. With such a configuration, after light emitted from a side portion of the light emitting layer 10 is reflected by the reflective film layer 60, the light is reflected again by the reflective film layer located on other side surface of the light emitting layer, and finally exits through the polarization structure, so that a light utilization rate may be improved without affecting the polarization degree of the exit light. A portion of the reflective film layer 60 located on each side surface of the light emitting layer 10 may be disposed obliquely, which is more helpful for light emitted from the side surface of the light emitting layer 10 to exit. A material for the reflective film layer 60 may include a high reflective material, or the reflective film layer 60 includes a plurality of film layers, for example, film layers with high reflectivity/reflectance and film layers with low reflectivity/reflectance in the plurality of film layers are alternately arranged.

In another embodiment, the light emitting chip further includes a light absorption film layer surrounding side portions of the light emitting layer 10 and configured to absorb light emitted from the side portions of the light emitting layer 10. With such a configuration, light emitted from side surfaces of the light emitting layer 10 does not affect the polarization degree of light emitted from the light emitting chip.

In an embodiment, the light emitting chip provided in the embodiments of the present application is a Mini LED or a Micro LED, where a size of the Mini LED is about 100 μm˜500 μm, and a size of the Micro LED is less than 100 μm.

When the polarization structure of the light emitting chip provided in the embodiments of the present application is formed on the protection layer, the polarization structure may be applied to a liquid crystal display device, instead of two polarizers located on two opposite sides of a liquid crystal display panel in the liquid crystal display device.

Through simulation, it is found that, whether light enters the polarization structure from the air or from the protection layer, in the entire visible light band, T_{TM} is above 90%, and PE is above 99.9975%, which is higher than a polarization degree of an existing polarizer. An absorptivity for the first linear polarized light is about 7%, and a reflectance/reflectivity for the first linear polarized light is about 3%; about 85% of the second linear polarized light is reflected by the polarization structure, the transmissivity for the second linear polarized light is 0, and an absorptivity for the second linear polarized light is 15%. It can be known that the transmissivity of the polarization structure for light is half of T_{TM}, which is about 45%; a proportion of light reflected by the polarization structure is about 45%, and a proportion of light absorbed by the polarization structure is about 10%.

One or more embodiments of the present application further provide a light emitting substrate. The light emitting substrate includes a driving circuit layer and a plurality of light emitting chips according to any one of the above embodiments, where the driving circuit layer includes one or more driving circuits for driving the light emitting chips.

In an embodiment, the light emitting substrate includes one or more light emitting chips with a color of light emitted being red, one or more light emitting chips with a color of light emitted being green, and one or more light emitting chips with a color of light emitted being blue. A wavelength of light emitted from the light emitting chip with a color of light emitted being red is in a range of 640 nm˜700 nm; a wavelength of light emitted from the light emitting chip with a color of light emitted being green is in a range of 500 nm˜580 nm; and a wavelength of light emitted from the light emitting chip with a color of light emitted being blue is 430 nm˜490 nm. With such a configuration, an exitance of the first linear polarized light and the polarization degree of the exit light may be improved.

In an embodiment, as shown in FIG. 39, the light emitting substrate further includes light absorption structures 70 located between adjacent light emitting chips. With such a configuration, light emitted from side surfaces of the light emitting layer 10 is absorbed by the light absorption structures, which avoids affecting the polarization degree of light emitted from the light emitting chips.

In another embodiment, as shown in FIG. 40, the light emitting substrate further includes an absorption layer 700 located on a light emitting side of the light emitting chips. The absorption layer is provided with a plurality of through holes 701, and orthographic projections of the light emitting layers of the light emitting chips on the absorption layer coincide with the through holes respectively. With such a configuration, only light passing through the polarization structures can exit, and other light, such as light emitted from side surfaces of the chips, is absorbed by the absorption layer, which may avoid affecting the polarization degree of light emitted from the light emitting chips.

In yet another embodiment, as shown in FIG. 41, the light emitting substrate further includes a reflective thin film layer 800 located on the light emitting side of the light emitting chips. The reflective thin film layer is provided with a plurality of openings 801, and orthographic projections of the light emitting layers of the light emitting chips on the reflective thin film layer coincide with the openings respectively. With such a configuration, only light passing through the polarization structures can exit, and light emitted from side surfaces of the chips is reflected by the reflective thin film layer, which may avoid affecting the polarization degree of light emitted from the light emitting chips.

One or more embodiments of the present application further provide a backlight module. The backlight module includes the light emitting substrate according to any one of the above embodiments.

In an embodiment, as shown in FIG. 34, the light emitting chip 100 is located on a side of the driving circuit layer 200, and the light emitting sides of the light emitting chips 100 face away from the driving circuit layer 200. That is, the backlight module is direct-type.

In another embodiment, as shown in FIG. 35, the backlight module includes a light guide plate 300 located on a side of the driving circuit layer 200, and the light emitting chip 100 is located on a side portion of the light guide plate 300. That is, the backlight module is edge-type.

In an embodiment, as shown in FIG. 34 and FIG. 35, the backlight module further includes a brightness enhancement film 400 located on the light emitting side of the light emitting chip 100. The brightness enhancement film 400 may improve a brightness of the backlight module.

In an embodiment, as shown in FIG. 34 and FIG. 35, the backlight module further includes a gas 600 located on a side of the brightness enhancement film 400 facing the light emitting chip 100. The gas 600 may be air.

According to the backlight module provided in the embodiments of the present application, since light emitted from the light emitting chip is linear polarized light, a film layer structure of the backlight module may be simplified. In addition to the light emitting chip, the light guide plate and the driving circuit layer, the backlight module may include only the brightness enhancement film, and a light transmissivity of the backlight module is greatly improved. Assuming that a transmissivity of a single film layer is 90%, the light transmissivity of the backlight module provided in the embodiments of the present application is 90%. A conventional backlight module includes a light emitting chip, a light guide plate, a driving circuit layer, two layers of brightness enhancement films, a color enhancement film, a diffusion film and a diffusion plate, and a light transmissivity of the conventional backlight module is 53%. Compared with the conventional backlight module, the light transmissivity of the backlight module provided in the embodiments of the present application is improved by 70%. Moreover, in a display device where the backlight module provided in the embodiments of the present application is incorporated, a polarizer located on a side of a liquid crystal display panel close to the backlight module may be spared. In a display device where the conventional backlight module is incorporated, a polarizer needs to be disposed on a side of a liquid crystal display panel close to the backlight module, and if a transmissivity of the polarizer is 50%, a utilization rate of light emitted from the light emitting chip in the conventional backlight module after passing through the polarizer is 26.5%. However, in the embodiments of the present application, since the polarizer does not need to be disposed on the side of the liquid crystal display panel close to the backlight module, the transmissivity for light emitted from the light emitting chip when reaching a surface of the liquid crystal display panel facing the backlight module is still 90%, which is improved by 240% compared with the conventional backlight module.

One or more embodiments of the present application further provide a display device.

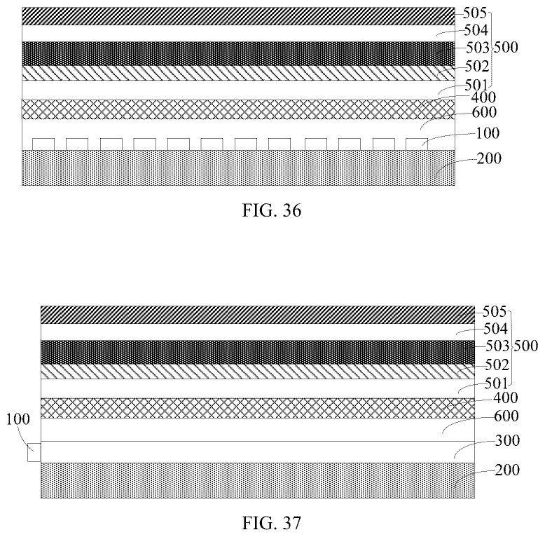

In an embodiment, as shown in FIG. 36 and FIG. 37, the display device includes a liquid crystal display panel 500 and the backlight module according to any one of the above embodiments. The liquid crystal display panel 500 is located on a light exit side of the backlight module. The liquid crystal display panel 500 includes a base plate 501 located on the light exit side of the backlight module, a pixel driving circuit layer 502 located on a side of the base plate 501 away from the backlight module, a liquid crystal layer 503 located on a side of the pixel driving circuit layer 502 away from the backlight module, a color film layer 504 located on a side of the liquid crystal layer 503 away from the backlight module, and a polarization film layer 505 located on a side of the color film layer 504 away from the backlight module. The polarization film layer may be a polarizer or the polarization structure in the embodiments of the present application.

In another embodiment, the display device includes a display panel, and the display panel is the light emitting substrate according to any one of the above embodiments.

In an embodiment, the display device further includes a housing, and the display panel is embedded in the housing.

The display device provided in the embodiments of the present application may be any suitable display device, including, but not limited to, any product or component with a display function, such as a mobile phone, a tablet computer, a television, a monitor, a notebook computer, a digital photo frame, a navigator, or an e-book. In particular, the display device may be an AR display device, a VR display device, an MR display device, etc.

It should be pointed out that, in the drawings, sizes of layers and areas may be exaggerated for clarity of illustration. It will also be understood that, when an element or layer is referred to as being “on” another element or layer, it can be directly on other element, or an intermediate layer may be present. In addition, it will be understood that, when an element or layer is referred to as being “below” another element or layer, it can be directly below other element, or more than one intermediate layer or element may be present. It will also be understood that, when a layer or element is referred to as being “between” two layers or elements, it can be the only layer between the two layers or elements, or more than one intermediate layer or element may be present. Similar reference signs indicate similar elements throughout the specification.

Other embodiments of the present application will be readily apparent to those skilled in the art after considering the specification and practicing the contents disclosed herein. The present application is intended to cover any variations, uses, or adaptations of the present application, which follow the general principle of the present application and include common knowledge or conventional technical means in the art that are not disclosed in the present application. The specification and examples are to be regarded as illustrative only. The true scope and spirit of the present application are pointed out by the following claims.

It is to be understood that the present application is not limited to the precise structures that have described and shown in the drawings, and various modifications and changes can be made without departing from the scope thereof. The scope of the application is to be limited only by the appended claims.

1. A light emitting chip, comprising:
a light emitting layer comprising a first semiconductor layer, a second semiconductor layer, and a quantum well layer between the first semiconductor layer and the second semiconductor layer;
a polarization structure on a side of the second semiconductor layer away from the quantum well layer, and configured to allow first linear polarized light in light emitted from the light emitting layer to exit and to reflect second linear polarized light in the light emitted from the light emitting layer, wherein a vibration direction of the first linear polarized light is perpendicular to a vibration direction of the second linear polarized light;
an auxiliary structure on a side of the polarization structure facing the light emitting layer, and configured to convert the second linear polarized light reflected by the polarization structure into light comprising the first linear polarized light and propagating toward the polarization structure;
a dielectric layer on the side of the second semiconductor layer away from the quantum well layer, and in direct contact with the second semiconductor layer.

2. The light emitting chip according to claim 1, wherein the polarization structure comprises a plurality of periodically arranged wire grids, and each of the wire grids comprises a metal layer and an inorganic material layer on a side of the metal layer facing the second semiconductor layer, wherein a thickness of the inorganic material layer is greater than a thickness of the metal layer.

3. The light emitting chip according to claim 1, wherein the polarization structure comprises a plurality of periodically arranged wire grids, and each of the wire grids comprises a metal layer and an inorganic material layer on a side of the metal layer away from the second semiconductor layer;
the dielectric layer is between the second semiconductor layer and the polarization structure, wherein a thickness of the inorganic material layer is greater than a thickness of the dielectric layer.

4. The light emitting chip according to claim 3, wherein a period of the wire grids is in a range of 40 nm˜200 nm, a width of the wire grids is in a range of 10 nm˜70 nm, a thickness of the metal layer is in a range of 60 nm˜160 nm, the thickness of the inorganic material layer is in a range of 120 nm˜200 nm, and the thickness of the dielectric layer is in a range of 0 nm˜40 nm or 120 nm˜180 nm.

5. The light emitting chip according to claim 1, wherein the polarization structure comprises a plurality of periodically arranged wire grids, and each of the wire grids comprises a metal layer; the dielectric layer is between the second semiconductor layer and the polarization structure, and the metal layer is in direct contact with the dielectric layer.

6. The light emitting chip according to claim 5, wherein a period of the wire grids is in a range of 40 nm˜200 nm, a width of the wire grids is in a range of 10 nm˜70 nm, a thickness of the metal layer is in a range of 60 nm˜160 nm, and a thickness of the dielectric layer is in a range of 0 nm˜40 nm or 120 nm˜180 nm.

7. The light emitting chip according to claim 1, wherein the polarization structure comprises a plurality of periodically arranged wire grids; the dielectric layer is between the second semiconductor layer and the polarization structure;
the light emitting chip further comprises an organic layer on a side of the dielectric layer away from the second semiconductor layer and in direct contact with the dielectric layer, and the organic layer comprises at least organic structures between adjacent wire grids of the wire grids, wherein a difference Δn2 between a refractive index of the dielectric layer and a refractive index of the organic layer is ≤0.4.

8. The light emitting chip according to claim 7, wherein each of the wire grids consist of a metal layer in direct contact with the dielectric layer;
a period of the wire grids is in a range of 40 nm˜200 nm, a width of the wire grids is in a range of 40 nm˜60 nm, a thickness of the metal layer is in a range of 70 nm˜90 nm, and a thickness of the dielectric layer is in a range of 10 nm˜30 nm or 170 nm˜200 nm.

9. The light emitting chip according to claim 1, wherein the polarization structure comprises a plurality of periodically arranged wire grids, and each of the wire grids comprises a metal layer and an inorganic material layer on a side of the metal layer facing the second semiconductor layer;
wherein the dielectric layer comprises a plurality of low refraction structures, the low refraction structures are between adjacent wire grids of the wire grids, and a material for the dielectric layer is an organic material; or
the dielectric layer is between the inorganic material layer and the second semiconductor layer; the light emitting chip further comprises an organic layer on a side of the dielectric layer away from the second semiconductor layer and in direct contact with the dielectric layer, wherein the organic layer comprises organic structures between adjacent wire grids of the wire grids, or the organic layer comprises the organic structures between adjacent wire grids of the wire grids and an organic material film layer between the inorganic material layer and the dielectric layer.

10. The light emitting chip according to claim 9, wherein a period of the wire grids is in a range of 40 nm˜200 nm, a width of the wire grids is in a range of 40 nm˜60 nm, a thickness of the metal layer is in a range of 100 nm˜120 nm, and a distance between a surface of the inorganic material layer away from the second semiconductor layer and a surface of the dielectric layer facing the second semiconductor layer is in a range of 170 nm˜200 nm.

11. The light emitting chip according to claim 1, further comprising: a protection layer on a side of the polarization structure away from the light emitting layer.

12. The light emitting chip according to claim 11, wherein the polarization structure comprises a plurality of periodically arranged wire grids;
wherein the dielectric layer is between the light emitting layer and the polarization structure; the light emitting chip further comprises an organic layer on a side of the dielectric layer away from the light emitting layer and being in direct contact with the dielectric layer, and the organic layer comprises at least organic structures between adjacent wire grids of the wire grids, wherein a difference Δn3 between a refractive index of the organic layer and a refractive index of the protection layer is ≤0.4; or
the dielectric layer comprises low refraction structures between adjacent wire grids of the wire grids, and a material for the dielectric layer is an organic material, wherein a difference Δn4 between a refractive index of the dielectric layer and a refractive index of the protection layer is ≤0.4.

13. The light emitting chip according to claim 1, further comprising:
a reflective film layer surrounding side portions of the light emitting layer; or
a light absorption film layer surrounding the side portions of the light emitting layer and configured to absorb light emitted from the side portions of the light emitting layer.

14. The light emitting chip according to claim 1, wherein
the auxiliary structure comprises a reflection layer or a scattering and reflection layer on a side of the light emitting layer away from the polarization structure; or
the auxiliary structure comprises a reflective material layer on the side of the light emitting layer away from the polarization structure and a first polarization film layer between the polarization structure and the reflective material layer, and the first polarization film layer is configured to shift a phase of light passing through the first polarization film layer by π/2; or
the auxiliary structure comprises a second polarization film layer on the side of the light emitting layer away from the polarization structure, and the second polarization film layer is configured to reflect the second linear polarized light and to convert the second linear polarized light into the first linear polarized light.

15. A light emitting substrate, comprising: a driving circuit layer and a plurality of light emitting chips according to claim 1, wherein the driving circuit layer comprises one or more driving circuits for driving the light emitting chips.

16. The light emitting substrate according to claim 15, wherein the plurality of light emitting chips comprise: a light emitting chip with a color of light emitted being red, a light emitting chip with a color of light emitted being green, and a light emitting chip with a color of light emitted being blue;
a wavelength of the light emitted from the light emitting chip with a color of the light emitted being red is in a range of 640 nm˜700 nm; a wavelength of the light emitted from the light emitting chip with a color of the light emitted being green is in a range of 500 nm˜580 nm; and a wavelength of the light emitted from the light emitting chip with a color of the light emitted being blue is in a range of 430 nm˜490 nm.

17. The light emitting substrate according to claim 15, further comprising:
light absorption structures located between adjacent light emitting chips of the light emitting chips; or
an absorption layer on a light emitting side of the light emitting chips and with a plurality of through holes, wherein orthographic projections of light emitting layers of the light emitting chips on the absorption layer coincide with the plurality of through holes respectively; or
a reflective layer on the light emitting side of the light emitting chips and with a plurality of openings, wherein orthographic projections of the light emitting layers of the light emitting chips on the reflective layer coincide with the openings respectively.

18. A backlight module, comprising: a light emitting substrate according to claim 15.

19. The backlight module according to claim 18, wherein the light emitting chips are on a side of the driving circuit layer, and a light emitting side of the light emitting chips faces away from the driving circuit layer; or the backlight module comprises a light guide plate on a side of the driving circuit layer, and the light emitting chips are on a side portion of the light guide plate; and/or
the backlight module further comprises a brightness enhancement film on a light emitting side of the light emitting chips.

20. (canceled)

21. (canceled)

22. The light emitting chip according to claim 1, wherein a refractive index of the dielectric layer is smaller than a refractive index of the second semiconductor layer and a difference Δn1 between the refractive index of the second semiconductor layer and the refractive index of the dielectric layer satisfies a following condition: 0.5≤Δn1≤1.0.
